(19) United States
(12) Patent Application Publication
(10) Pub. No.: US 2024/0332370 A1
(43) Pub. Date: Oct. 3, 2024

(54) NITRIDE SEMICONDUCTOR DEVICE

(71) Applicant: ROHM CO., LTD., Kyoto-Shi (JP)

(72) Inventor: Hirotaka OTAKE, Kyoto-Shi (JP)

(73) Assignee: ROHM CO., LTD., Kyoto-Shi (JP)

(21) Appl. No.: 18/618,049

(22) Filed: Mar. 27, 2024

(30) Foreign Application Priority Data
Mar. 29, 2023 (JP) 2023-053364

(51) Int. Cl. H01L 29/20; H01L 23/31; H01L 27/06; H01L 29/40; H01L 29/417; H01L 29/47

(52) U.S. Cl. CPC H01L 29/2003; H01L 23/3171; H01L 27/0629; H01L 29/402; H01L 29/41725; H01L 29/475

(57) ABSTRACT

A nitride semiconductor device includes a passivation layer having a first opening and a second opening arranged to sandwich a gate layer along an X-axis direction. The passivation layer has a third opening arranged apart from the first opening and the second opening along the X-axis direction. The nitride semiconductor device includes: a first electrode in contact with an electron supply layer within the first opening; a second electrode in contact with the electron supply layer within the second opening; and a third electrode in contact with the electron supply layer within the third opening. Furthermore, the nitride semiconductor device includes an anode layer made of a nitride semiconductor containing acceptor-type impurities. The second opening is disposed at a boundary between a transistor region and a diode region. The second electrode is used as both a source electrode of a transistor and an anode electrode of a diode.

### CROSS-REFERENCE TO RELATED APPLICATION

This application is based upon and claims the benefit of priority from Japanese Patent Application No. 2023-053364, filed on Mar. 29, 2023, the entire contents of which are incorporated herein by reference.

### TECHNICAL FIELD

The present disclosure relates to a nitride semiconductor device.

### BACKGROUND

Currently, high electron mobility transistors (HEMTs) using group III nitride semiconductors such as gallium nitride (GaN) (hereinafter sometimes simply referred to as “nitride semiconductors”) are being commercialized. HEMT uses two-dimensional electron gas (2 DEG) formed near the interface of a semiconductor heterojunction as a conductive path (channel). Power devices using HEMTs are considered to be devices that can achieve low on-resistance and high-speed, high-frequency operation compared to typical silicon (Si) power devices.

For example, the nitride semiconductor device described in Patent Document 1 includes an electron travelling layer composed of a gallium nitride (GaN) layer and an electron supply layer composed of an aluminum gallium nitride (AlGaN) layer. 2 DEG is formed in the electron travelling layer near the heterojunction interface between the electron travelling layer and the electron supply layer. In addition, in the nitride semiconductor device of Patent Document 1, a gate layer (for example, a p-type GaN layer) containing acceptor-type impurities is provided on the electron travelling layer at a position directly below the gate electrode. In this structure, in the region directly below the gate layer, the gate layer enhances the frequency band energy of the conduction band near the heterojunction interface between the electron travelling layer and the electron supply layer, so that the channel directly below the gate layer disappears, thus achieving normal disconnection.

### BACKGROUND TECHNICAL DOCUMENTS

### Patent Documents

[Patent Document 1] Japanese Patent Application Publication No. 2017-73506

### BRIEF DESCRIPTION OF THE DRAWINGS

FIG. 1 is an exemplary schematic top view of a nitride semiconductor device according to a first embodiment.

FIG. 2 is an enlarged schematic top view of a portion of the nitride semiconductor device of FIG. 1.

FIG. 3 is a schematic cross-sectional view of the nitride semiconductor device taken along line F3-F3 in FIG. 2.

FIG. 4 is an enlarged schematic top view of a portion of the nitride semiconductor device of FIG. 1.

FIG. 5 is a schematic cross-sectional view of the nitride semiconductor device taken along line F5-F5 in FIG. 4.

FIG. 6 is a schematic cross-sectional view showing a manufacturing step of the nitride semiconductor device of FIG. 5.

FIG. 7 is a schematic cross-sectional view showing a manufacturing step subsequent to the step shown in FIG. 6.

FIG. 8 is a schematic cross-sectional view showing a manufacturing step subsequent to the step shown in FIG. 7.

FIG. 9 is a schematic cross-sectional view showing a manufacturing step subsequent to the step shown in FIG. 8.

FIG. 10 is a schematic cross-sectional view showing a manufacturing step subsequent to the step shown in FIG. 9.

FIG. 11 is a schematic cross-sectional view showing a manufacturing step subsequent to the step shown in FIG. 10.

FIG. 12 is a schematic cross-sectional view showing a manufacturing step subsequent to the step shown in FIG. 11.

FIG. 13 is a schematic cross-sectional view showing a manufacturing step subsequent to the step shown in FIG. 12.

FIG. 14 is a schematic cross-sectional view showing a manufacturing step subsequent to the step shown in FIG. 13.

FIG. 15 is a schematic cross-sectional view showing a manufacturing step subsequent to the step shown in FIG. 14.

FIG. 16 is a schematic cross-sectional view of an exemplary nitride semiconductor device according to a modified example.

FIG. 17 is a schematic cross-sectional view of an exemplary nitride semiconductor device according to a modified example.

FIG. 18 is a schematic cross-sectional view of an exemplary nitride semiconductor device according to a modified example.

FIG. 19 is an exemplary schematic top view of a nitride semiconductor device according to a second embodiment.

FIG. 20 is a schematic cross-sectional view of the nitride semiconductor device taken along line F20-F20 in FIG. 19.

FIG. 21 is a schematic top view of an exemplary nitride semiconductor device according to a modified example.

### DETAILED DESCRIPTION OF THE EMBODIMENTS

Hereinafter, several embodiments of the nitride semiconductor device of the present disclosure will be described with reference to the accompanying drawings. In addition, the components shown in the drawings are not necessarily drawn on a fixed scale for simple and clear illustration. In order to facilitate understanding, hatching lines may be omitted in cross-sectional views. The drawings merely illustrate embodiments of the present disclosure and should not be construed as limiting the present disclosure. Terms such as “first”, “second”, and “third” in the present disclosure are only used to distinguish the objects and do not rank the objects.

The following detailed description includes devices, systems, and methods that embody exemplary embodiments of the present disclosure. This detailed description is for illustrative purposes only and is not intended to limit the embodiments of the present disclosure or the applications and uses of such embodiments.

The expression “at least one” used in this specification means the desired option of “one or more”. As an example, if the number of options is two, then the expression “at least one” used in this specification means both options of “only one” or “two”. As another example, the expression “at least one” used in this specification means the options of “only one” or “any combination of two or more” if the number of options is three or more.

### First Embodiment

### (Schematic Configuration of Nitride Semiconductor Device)

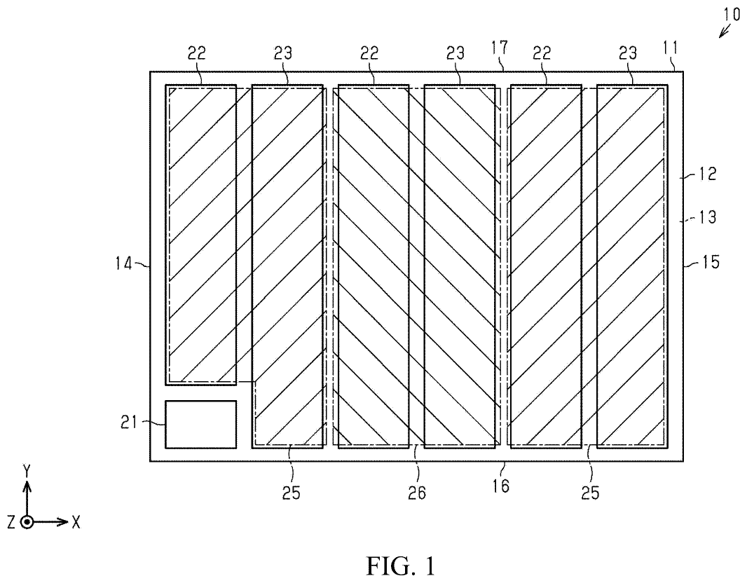

FIG. 1 is a schematic top view of an exemplary nitride semiconductor device 10 according to a first embodiment.

In one example, the nitride semiconductor device 10 is formed in a rectangular flat plate shape. For convenience of explanation, a thickness direction of the nitride semiconductor device 10 is referred to as the Z-axis direction. Two axis directions orthogonal to the Z-axis direction and orthogonal to each other are referred to as the X-axis direction and the Y-axis direction. In addition, the term “top view” used in the present disclosure refers to viewing the nitride semiconductor device 10 in the Z-axis direction shown in FIG. 1.

The nitride semiconductor device 10 includes a chip body 11. The chip body 11 is formed in a rectangular shape in top view. The chip body 11 includes an upper surface 12 and a lower surface 13 facing the opposite side to the upper surface 12. Regarding the upper surface 12 and the lower surface 13, in one example, the upper surface 12 and the lower surface 13 are formed in a rectangular shape that is longer in the X-axis direction with respect to the Y-axis direction.

The chip body 11 includes a plurality of side surfaces 14, 15, 16, and 17. Each side surface 14 to 17 is a surface connecting the upper surface 12 and the lower surface 13. In one example, the side surfaces 14 to 17 are surfaces orthogonal to both the upper surface 12 and the lower surface 13. The side surfaces 14 and 15 face opposite sides in the X-axis direction. The side surfaces 16 and 17 face opposite sides in the Y-axis direction.

The nitride semiconductor device 10 includes a gate pad 21, a source pad 22 and a drain pad 23 formed on the upper surface 12. The gate pad 21, the source pad 22 and the drain pad 23 may constitute external connection terminals of the nitride semiconductor device 10. In one example, the nitride semiconductor device 10 includes one gate pad 21, a plurality of source pads 22 and a plurality of drain pads 23.

The gate pad 21 is formed in a rectangular shape in top view. The gate pad 21 is arranged at a corner of the upper surface 12. In one example, the gate pad 21 is disposed at the corner of the upper surface 12 formed by the side surfaces 14 and 16.

The plurality of source pads 22 and the plurality of drain pads 23 are formed along a straight line extending from the side surface 16 to the side surface 17 of the nitride semiconductor device 10, that is, along the Y-axis direction in a top view. Furthermore, the plurality of source pads 22 and the plurality of drain pads 23 are alternately arranged in a direction intersecting the direction in which they extend, in one example, the X-axis direction orthogonal to the Y-axis direction.

The nitride semiconductor device 10 includes a high electron mobility transistor (HEMT) using a nitride semiconductor and a diode using a nitride semiconductor. The nitride semiconductor device 10 includes a plurality of transistors and a plurality of diodes. The plurality of transistors includes a gate electrode electrically connected to the gate pad 21, a source electrode electrically connected to the source pad 22, and a drain electrode electrically connected to the drain pad 23. The plurality of diodes includes an anode electrode electrically connected to the source pad 22 and a cathode electrode electrically connected to the drain pad 23. That is, the plurality of diodes included in the nitride semiconductor device 10 are connected in reverse parallel with respect to the transistors included in the nitride semiconductor device 10.

### (Configuration of First and Second Regions)

As shown in FIG. 1, the nitride semiconductor device 10 includes a first region 25 and a second region 26. In one example, the first region 25 is provided at both ends of the chip body 11 in the X-axis direction in top view. The second region 26 is arranged at the center of the nitride semiconductor device 10 in the X-axis direction. The first regions 25 are arranged sandwiching the second region 26 in the X-axis direction. In one example, the first region 25 includes only the transistor among the transistor and the diode. In one example, the second region 26 includes both the transistor and the diode. The first region 25 and the second region 26 shown in FIG. 1 serve as an example. For example, the first region 25 and the second region 26 are shown to be separated in FIG. 1. In addition, in the X-axis direction and the Y-axis direction, the first region 25 and the second region 26 are shown smaller than the source pad 22 and the drain pad 23. Regarding these, the arrangement, shape, and size of the first region 25 and the second region 26 can be appropriately changed.

### (Configuration of First and Second Regions)

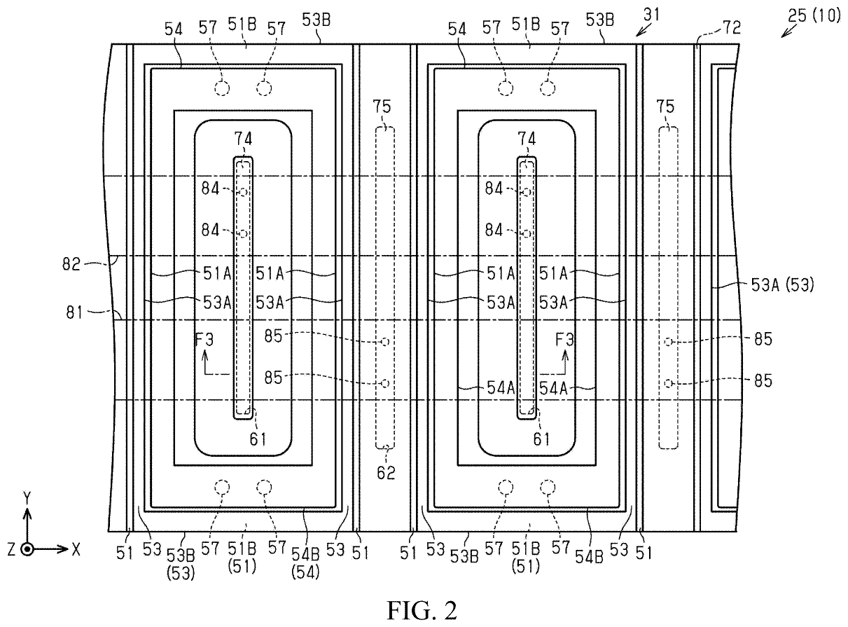

The configuration of the first region 25 and the second region 26 included in the nitride semiconductor device 10 will be described with reference to FIGS. 2 to 5.

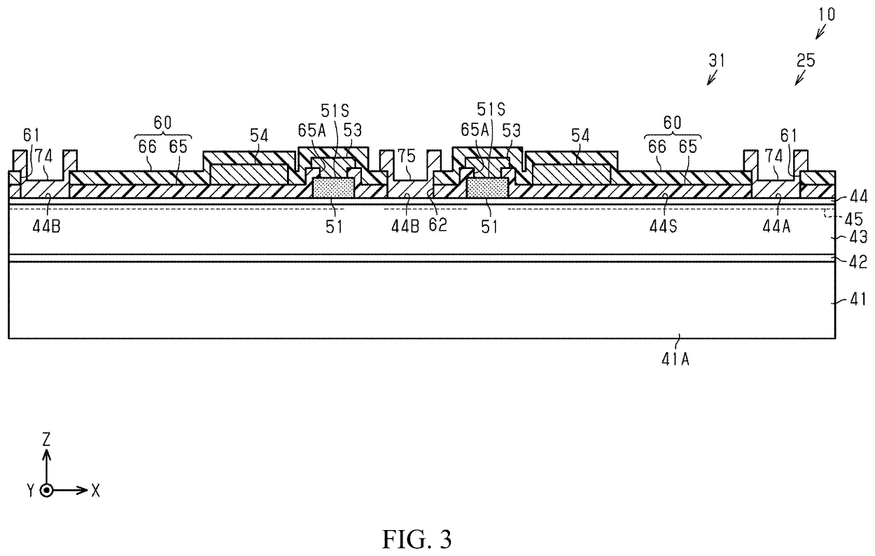

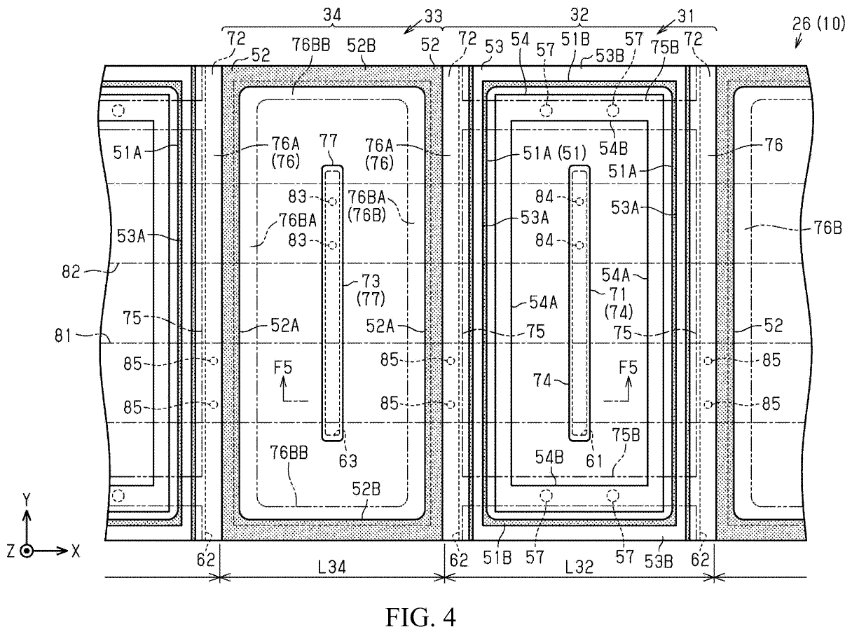

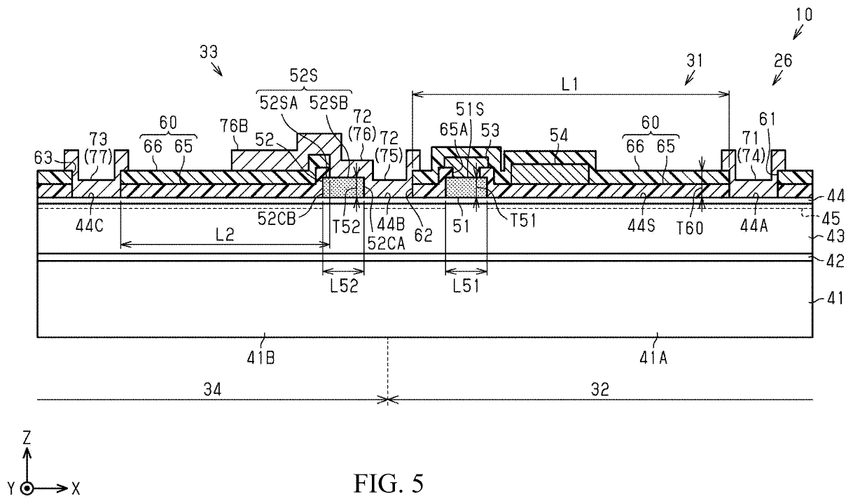

FIG. 2 is an enlarged schematic top view of a portion of the nitride semiconductor device 10 of FIG. 1, more specifically, a portion of the first region 25 of FIG. 1. FIG. 3 is a schematic cross-sectional view of the nitride semiconductor device 10 taken along line F3-F3 in FIG. 2. FIG. 4 is an enlarged schematic top view of a portion of the nitride semiconductor device 10 of FIG. 1, more specifically, a portion of the second region 26 of FIG. 1. FIG. 5 is a schematic cross-sectional view of the nitride semiconductor device taken along line F5-F5 in FIG. 4. In addition, in FIGS. 2 and 4, the source electrode 75 and the anode electrode 76 (the anode extending portion 76B) are shown by two-dot chain lines. In addition, in FIGS. 4 and 5, the gate layer 51 and the anode layer 52 are hatched with dots for easy identification.

As shown in FIGS. 2 and 3, the first region 25 includes a transistor region 32 in which a transistor 31 is formed. The first region 25 includes a plurality of transistor regions 32. The plurality of transistor regions 32 are arranged adjacent to each other in the X-axis direction. In FIG. 2, it is shown with respect to the X-axis direction. In one example, the same as the X-axis direction, a plurality of transistor regions 32 are arranged adjacent to each other in the Y-axis direction. The first region 25 is a region that does not include the diode 33 as shown in FIGS. 4 and 5. The first region 25 can be said to include only the transistor region 32 among the transistor region 32 and the diode region 34.

As shown in FIGS. 4 and 5, the second region 26 includes the transistor region 32 in which the transistor 31 is formed and the diode region 34 in which the diode 33 is formed. The second region 26 includes a plurality of transistor regions 32 and a plurality of diode regions 34. The second region 26 can be said to include both the transistor region 32 and the diode region 34.

The diode region 34 and the transistor region 32 are provided adjacent to each other in the X-axis direction. In one example, the transistor regions 32 and the diode regions 34 are alternately provided in the X-axis direction. In addition, in FIG. 4, it is shown with respect to the X-axis direction. In one example, in the Y-axis direction, plural transistor regions 32 are arranged adjacent to each other and plural diode regions 34 are arranged adjacent to each other. A length L34 of the diode region 34 in the X-axis direction is less than a length L32 of the transistor region 32 in the X-axis direction.

### (Configuration of Transistors and Diodes)

Next, the configurations of the transistor 31 included in the transistor region 32 and the diode 33 included in the diode region 34 will be described.

As described above, the first region 25 includes only the transistor 31 among the transistor 31 and the diode 33. In addition, the second region 26 includes both the transistor 31 and the diode 33. Therefore, the transistor 31 and the diode 33 included in the second region 26 will be described with reference to FIGS. 4 and 5. The transistor 31 included in the first region 25 shown in FIGS. 2 and 3 is denoted by the same reference numerals as the transistor 31 shown in FIGS. 4 and 5.

In the second region 26, the transistor 31 is composed of a nitride semiconductor layer on a transistor region 41A of a substrate 41 and components arranged on the nitride semiconductor layer. The diode 33 is composed of a nitride semiconductor layer on a diode region 41B of the substrate 41 and components arranged on the nitride semiconductor layer. These components will be described.

As shown in FIG. 5, the nitride semiconductor device 10 includes the substrate 41, a buffer layer 42 formed on the substrate 41, an electron travelling layer 43 formed on the buffer layer 42, and an electron supply layer 44 formed on the electron travelling layer 43.

The substrate 41 includes the transistor region 41A and the diode region 41B. The transistor region 41A of the substrate 41 is a portion of the substrate 41 included in the transistor region 32. The diode region 41B of the substrate 41 is a portion of the substrate 41 included in the diode region 34. The diode region 41B and the transistor region 41A are provided adjacent to each other in the X-axis direction. In one example, in the second region 26, the transistor regions 41A and the diode regions 41B are alternately provided in the X-axis direction. In the following description, the regions of the substrate 41 are not distinguished, but the transistor region 32 and the diode region 34 are used for description. In addition, in the first region 25, the substrate 41 includes the transistor region 41A and does not include the diode region 41B.

The buffer layer 42 is formed on the substrate 41 in a manner crossing both the transistor region 32 and the transistor region 32. The electron travelling layer 43 is formed on the buffer layer 42 in a manner crossing both the transistor region 32 and the transistor region 32. The electron supply layer 44 is formed on the electron travelling layer 43 in a manner crossing both the transistor region 32 and the transistor region 32.

The substrate 41 may be formed of silicon (Si), silicon carbide (SIC), GaN, sapphire, or other substrate materials. For example, the substrate 41 is a conductive Si substrate. A thickness of the substrate 41 can be, for example, between about 200 μm and about 1,500 μm. In addition, the Z-axis direction shown in each figure is a direction orthogonal to the main surface of the substrate 41.

The buffer layer 42 may be located between the substrate 41 and the electron travelling layer 43. In one example, the buffer layer 42 may be formed of any material that can facilitate the epitaxial growth of the electron travelling layer 43. The buffer layer 42 may include one or more nitride semiconductor layers.

In one example, the buffer layer 42 may include at least one of an aluminum nitride (AlN) layer, an aluminum gallium nitride (AlGaN) layer, and a graded AlGaN layer having different aluminum (Al) compositions. For example, the buffer layer 42 may be formed of a single AlN layer, a single AlGaN layer, a layer having an AlGaN/GaN superlattice structure, a layer having an AlN/AlGaN superlattice structure, or a layer having an AlN/GaN superlattice structure. In addition, in order to suppress the leakage current in the buffer layer 42, impurities may be introduced into a portion of the buffer layer 42 to make the buffer layer 42 semi-insulating. Under such circumstance, the impurity is, for example, carbon (C) or iron (Fe), and a concentration of the impurity can be, for example, 4×10¹⁶ cm⁻³ or more.

The electron travelling layer 43 may be formed of a nitride semiconductor. The electron travelling layer 43 corresponds to the first nitride semiconductor layer. For example, electron travelling layer 43 may be a GaN layer. A thickness of the electron travelling layer 43 may be, for example, between about 0.5 μm and about 2 μm. In addition, in order to suppress the leakage current in the electron travelling layer 43, impurities may be introduced into a portion of the electron travelling layer 43 to make the electron travelling layer 43 semi-insulating except for the surface layer region. Under such circumstance, the impurity is, for example, C, and the concentration of the impurity may be, for example, 1×10¹⁹ cm⁻³ or more in terms of peak concentration.

The electron supply layer 44 may be formed of a nitride semiconductor. The electron supply layer 44 corresponds to the second nitride semiconductor layer. For example, the electron supply layer 44 may be an AlGaN layer. In the AlGaN layer, the more the Al composition is, the larger the band gap will be. Therefore, the electron supply layer 44 which is an AlGaN layer has a larger band gap than the electron travelling layer 43 which is a GaN layer. For example, the electron supply layer 44 is composed of AlₓGa₁₋ₓN. Here, x has a range of 0.1<x<0.4, more preferably 0.2<x<0.3, but is not necessarily limited thereto. A thickness of the electron supply layer 44 may be, for example, between about 5 nm and about 20 nm.

The electron travelling layer 43 and the electron supply layer 44 are composed of nitride semiconductors having different lattice constants. Therefore, a lattice mismatch occurs in the combination of the nitride semiconductor (e.g., GaN) constituting the electron travelling layer 43 and the nitride semiconductor (e.g., AlGaN) constituting the electron supply layer 44. Due to the spontaneous polarization of the electron travelling layer 43 and the electron supply layer 44 and the piezoelectric polarization caused by the stress on the heterojunction portion of the electron supply layer 44, the energy level of the conduction band of the electron travelling layer 43 near the heterojunction interface of the electron supply layer 43 and the electron supply layer 44 is lower than the Fermi level. As a result, the two-dimensional electron gas (2 DEG) 45 diffuses in the electron travelling layer 43 at a position close to the heterojunction interface between the electron travelling layer 43 and the electron supply layer 44 (for example, a distance of approximately several nm from the interface).

The nitride semiconductor device 10 further includes a gate layer 51 and an anode layer 52 formed on the electron supply layer 44, a gate electrode 53 formed on the gate layer 51, and a passivation layer 60.

### (Gate Layer)

The gate layer 51 is formed on the electron supply layer 44 in the transistor region 32. The gate layer 51 may be formed of a nitride semiconductor having a smaller band gap than the electron supply layer 44. As an example, when the electron supply layer 44 is an AlGaN layer, the gate layer 51 may be a GaN layer doped with acceptor-type impurities, that is, a p-type GaN layer. The acceptor-type impurity may be at least one of zinc (Zn), magnesium (Mg), and carbon (C), for example. The maximum concentration of the acceptor-type impurities in the gate layer 51 is, for example, between about 7×10¹⁸ cm⁻³ and about 1×10²⁰ cm⁻³.

When the gate layer 51 is formed of a nitride semiconductor containing acceptor-type impurities, the energy levels of the electron travelling layer 43 and the electron supply layer 44 are raised. Therefore, in the region directly below the gate layer 51, the energy level of the conduction band of the electron travelling layer 43 near the heterojunction interface between the electron travelling layer 43 and the electron supply layer 44 is almost the same as or higher than the Fermi level. Therefore, under zero bias voltage when no voltage is applied to the gate electrode 53, the 2 DEG 45 is not formed in the electron travelling layer 43 in the region directly below the gate layer 51. On the other hand, in the transistor region 32, the 2 DEG 45 is formed in the electron travelling layer 43 in a region other than the region directly below the gate layer 51.

In this way, due to the presence of the gate layer 51 doped with acceptor-type impurities, the 2 DEG 45 disappears in the region directly below the gate layer 51. As a result, the normally-off operation of the transistor 31 is realized. When an appropriate on-voltage is applied to the gate electrode 53, a channel using the 2 DEG 45 is formed in the electron travelling layer 43 in the region directly below the gate electrode 53, so that the source-drain conduction occurs.

A film thickness T51 of the gate layer 51 is not particularly limited and can be appropriately determined taking into account various parameters such as the gate withstand voltage. For example, the film thickness T51 of the gate layer 51 can be between about 80 nm and about 150 nm. In addition, a cross-sectional shape of the gate layer 51 is not particularly limited. The gate layer 51 may have, for example, a rectangular shape, a trapezoidal shape, a ridge shape, or other arbitrary shapes in the cross-section along the ZX plane in FIG. 5.

### (Anode Layer)

The anode layer 52 is formed on the electron supply layer 44 in the diode region 34. The anode layer 52 may be formed of a nitride semiconductor having a smaller band gap than the electron supply layer 44. As an example, when the electron supply layer 44 is an AlGaN layer, the anode layer 52 may be a GaN layer doped with acceptor-type impurities, that is, a p-type GaN layer. The acceptor-type impurity may be at least one of zinc (Zn), magnesium (Mg), and carbon (C), for example. The maximum concentration of acceptor-type impurities in the anode layer 52 is, for example, between about 7×10¹⁸ cm⁻³ and about 1×10²⁰ cm⁻³.

When the anode layer 52 is formed of a nitride semiconductor containing acceptor-type impurities, 2 DEG is not formed in the electron travelling layer 43 in the region directly below the anode layer 52, similarly to the gate layer 51. In one example, a length L52 of the anode layer 52 in the X-axis direction is equal to the length L51 of the gate layer 51 in the X-axis direction. In one example, a film thickness T52 of the anode layer 52 is equal to the film thickness T51 of the gate layer 51. In addition, the cross-sectional shape of the anode layer 52 is not particularly limited. The anode layer 52 may have, for example, a rectangular shape, a trapezoidal shape, a ridge shape, or other arbitrary shapes in the cross-section along the ZX plane in FIG. 5.

### (Passivation Layer)

The passivation layer 60 is formed to cover the electron supply layer 44, the gate layer 51, the gate electrode 53 and the anode layer 52. In one example, the passivation layer 60 is in contact with the electron supply layer 44, the gate layer 51, the gate electrode 53 and the anode layer 52.

The passivation layer 60 includes a first opening 61, a second opening 62, and a third opening 63. The first opening 61 and the second opening 62 are arranged sandwiching the gate layer 51. The first opening 61 and the second opening 62 are arranged apart from the gate layer 51. A distance between the first opening 61 and the gate layer 51 is greater than a distance between the second opening 62 and the gate layer 51. It can be said that the first opening 61 is formed further apart from the gate layer 51 than the second opening 62. It can be said that the gate layer 51 is arranged closer to the second opening 62 than the first opening 61.

The third opening 63 is arranged apart from the first opening 61 and the second opening 62 in the X-axis direction. The third opening 63 is arranged on the opposite side to the first opening 61 with respect to the second opening 62.

The second opening 62 is provided at the boundary between the transistor region 32 and the diode region 34. The first opening 61 is provided in the transistor region 32. In one example, the first opening 61 is provided at the center of the transistor region 32 in the X-axis direction. The third opening 63 is provided in the diode region 34. In one example, the third opening 63 is provided at the center of the diode region 34 in the X-axis direction. As shown in FIG. 4, the first opening 61, the second opening 62, and the third opening 63 are formed to extend in the Y-axis direction.

The first opening 61 is formed to expose a portion of the upper surface 44S of the electron supply layer 44. The first opening 61 exposes the upper surface 44S of the electron supply layer 44 as a first connection region 44A. The third opening 63 is formed to expose a portion of the upper surface 44S of the electron supply layer 44. The third opening 63 exposes the upper surface 44S of the electron supply layer 44 as a third connection region 44C. The second opening 62 is formed to expose a portion of the upper surface 44S of the electron supply layer 44. The second opening 62 exposes the upper surface 44S of the electron supply layer 44 as a second connection region 44B. In addition, the second opening 62 can be said to be formed so as to expose the anode layer 52. The second opening 62 can be said to be formed so as to expose the anode layer 52 and the electron supply layer 44.

The anode layer 52 includes an upper surface 52S and side surfaces 52CA and 52CB. The upper surface 52S of the anode layer 52 faces the same direction as the upper surface 44S of the electron supply layer 44. The side surfaces 52CA and 52CB face opposite sides to each other in the X-axis direction. The side surface 52CA of the anode layer 52 faces the gate layer 51. The passivation layer 60 is formed to cover a portion 52SB of the upper surface 52S on the opposite side to the gate layer 51 and the side surface 52CB of the anode layer 52. Furthermore, the second opening 62 of the passivation layer 60 is formed to expose a portion 52SA of the upper surface 52S that is close to the gate layer 51 and the side surface 52CA.

The passivation layer 60 includes a first passivation film 65 and a second passivation film 66. The first passivation film 65 is formed on the electron supply layer 44. The first passivation film 65 is formed to cover the electron supply layer 44, the gate layer 51 and the anode layer 52. The second passivation film 66 is formed on the first passivation film 65. The second passivation film 66 covers the gate electrode 53.

The first passivation film 65 includes a gate opening 65A. The gate opening 65A exposes a portion of the upper surface of the gate layer 51. The gate electrode 53 is in contact with the upper surface 51S of the gate layer 51 through the gate opening 65A of the first passivation film 65. In one example, the gate electrode 53 includes a first portion embedded in the gate opening 65A and a second portion formed on the first portion. In one example, the length of the first portion in the X-axis direction is less than the length of the gate layer 51 in the X-axis direction. The second portion extends from the first portion in the X-axis direction. The second portion covers the peripheral edge of the gate opening 65A of the first passivation film 65.

The passivation layer 60 may be made of a material comprising any one of silicon nitride (SiN), silicon dioxide (SiO₂), silicon oxynitride (SiON), aluminum oxide (Al₂O₃), AlN, and aluminum oxynitride (AlON), for example. In one example, the passivation layer 60 is formed of a material including SiN. A film thickness T60 of the passivation layer 60 can be, for example, between about 50 nm and about 200 nm. In one example, the film thickness T60 of the passivation layer 60 may be 100 nm.

The first passivation film 65 and the second passivation film 66 may be formed of the same material. In addition, the first passivation film 65 and the second passivation film 66 may be formed of different materials.

### (Gate Electrode)

The gate electrode 53 may be formed of one or more metal layers. In one example, the gate electrode 53 may be a titanium nitride (TiN) layer. In this case, the gate electrode 53 is in Schottky contact with the gate layer 51. Alternatively, the gate electrode 53 may be composed of a first metal layer (for example, a Ti layer) and a second metal layer (for example, a TiN layer) provided on the first metal layer. The gate electrode 53 can be said to be formed of a material that is in Schottky contact with the gate layer 51. The thickness of the gate electrode 53 may be, for example, between about 50 nm and about 300 nm.

In the examples of FIGS. 3 and 5, the gate electrode 53 is arranged on a portion of the upper surface of the gate layer 51. The first portion of the gate electrode 53 in contact with the gate layer 51 has a width smaller than that of the gate layer 51 in the X-axis direction. Compared with the case where the gate electrode 53 is formed with the same width as the gate layer 51 in the X-axis direction, such gate layer 51 and gate electrode 53 are advantageous in terms of reducing gate leakage current. However, the gate electrode 53 may be formed with the same width as the gate layer 51.

### (First Electrode, Second Electrode, Third Electrode)

The nitride semiconductor device 10 includes a first electrode 71, a second electrode 72, and a third electrode 73. The first electrode 71 is in contact with the first connection region 44A of the electron supply layer 44 within the first opening 61. The first electrode 71 is in ohmic contact with the 2 DEG 45 directly below the electron supply layer 44 via the electron supply layer 44. The second electrode 72 is in contact with the second connection region 44B of the electron supply layer 44 within the second opening 62. The second electrode 72 is in ohmic contact with the 2 DEG 45 directly below the electron supply layer 44 via the electron supply layer 44. The third electrode 73 is in contact with the third connection region 44C of the electron supply layer 44 in the third opening 63. The third electrode 73 is in ohmic contact with the 2 DEG 45 directly below the electron supply layer 44 via the electron supply layer 44. The nitride semiconductor device 10 can be said to include the first electrode 71 in contact with the electron supply layer 44 in the first opening 61, the second electrode 72 in contact with the electron supply layer 44 in the second opening 62, and the third electrode 73 in contact with the electron supply layer 44 in the third opening 63. It can be said that the first electrode 71, the second electrode 72 and the third electrode 73 are formed of a material that is in ohmic contact with the electron supply layer 44.

The second opening 62 is formed to expose the anode layer 52. Therefore, the second electrode 72 is in contact with the anode layer 52 exposed through the second opening 62. The second electrode 72 is in ohmic contact with the anode layer 52. The second electrode 72 may be formed of a material that is in ohmic contact with the anode layer 52.

The first electrode 71, the second electrode 72, and the third electrode 73 may be composed of one or more metal layers. The first electrode 71, the second electrode 72, and the third electrode 73 can be formed of, for example, at least one material of a Ti layer, a TiCu layer, a TiN layer, an Al layer, an AlSiCu layer, and an AlCu layer. In one example, the first electrode 71, the second electrode 72, and the third electrode 73 may be TiCu layers. The first electrode 71, the second electrode 72, and the third electrode 73 may be formed of the same material. At least one of the first electrode 71, the second electrode 72, and the third electrode 73 may be formed of a different material from the other electrodes. In addition, the first electrode 71, the second electrode 72, and the third electrode 73 may be formed of different materials.

The first electrode 71 is a drain electrode formed in the transistor region 32. The third electrode 73 is a cathode electrode and is provided at a position opposite to and separated from the first electrode 71 with respect to the second electrode 72 in the diode region 34 in the X-axis direction. The second opening 62 exposes the electron supply layer 44 and the anode layer 52. Therefore, the second electrode 72 is in contact with both the electron supply layer 44 and the anode layer 52, and serves as a source electrode and an anode electrode simultaneously. In the following description, the first electrode 71 may be described as the drain electrode 74, the third electrode 73 may be described as the cathode electrode 77, and the second electrode 72 may be described as the source electrode 75 or the anode electrode 76.

A distance L1 between the first opening 61 and the second opening 62 in the transistor region 32 corresponds to the drain-source distance of the transistor 31. A distance L2 between the second opening 62 and the third opening 63 in the diode region 34 corresponds to the anode-cathode distance of the diode 33. The distance L2 in the diode region 34 is shorter than the distance L1 in the transistor region 32.

The anode electrode 76 may include an anode extension 76B. In one example, the anode electrode 76 includes an anode electrode portion 76A and an anode extending portion 76B that is continuous with the anode electrode portion 76A. The anode electrode portion 76A includes a portion in contact with the electron travelling layer 43 and the anode layer 52. The anode extending portion 76B may be formed integrally with the anode electrode portion 76A. The anode extending portion 76B is provided in the diode region 34. The anode extending portion 76B extends from the anode layer 52 toward the cathode electrode 77.

The nitride semiconductor device 10 includes a transistor field plate electrode 54. The transistor field plate electrode 54 is provided on the electron supply layer 44 in the transistor region 32 and between the gate layer 51 and the drain electrode 74. The transistor field plate electrode 54 is embedded in the passivation layer 60. Specifically, the transistor field plate electrode 54 is arranged on the first passivation film 65 and covered by the second passivation film 66.

### (Planar Structure of the Transistor Region and the Diode Region)

As shown in FIG. 4, the gate layer 51 is formed in a ring shape in top view. The gate layer 51 includes two main body portions 51A, which are disposed sandwiching the drain electrode 74 in the X-axis direction and extend in the Y-axis direction; and connection portions 51B located on one side and the other side of the drain electrode 74 in the Y-axis direction and connect the two adjacent main body portions 51A to each other. The gate layer 51 can be said to be formed so as to surround the drain electrode 74 in a top view. The drain electrode 74 can be said to be surrounded by the gate electrode layer 51 in a top view.

The gate electrode 53 is formed in a ring shape in top view. The gate electrode 53 includes two main body portions 53A, which are disposed sandwiching the drain electrode 74 in the X-axis direction and extend in the Y-axis direction; and connection portions 53B located on one side and the other side of the drain electrode 74 in the Y-axis direction and connect the two main body portions 53A to each other. The gate electrode 53 can be said to be formed so as to surround the drain electrode 74 in a top view. The drain electrode 74 can be said to be surrounded by the gate electrode 53 in a top view. The gate electrode 53 is arranged on the gate layer 51. The main body portion 53A of the gate electrode 53 is arranged on the main body portion 51A of the gate layer 51. The connection portion 53B of the gate electrode 53 is arranged on the connection portion 51B of the gate layer 51.

The transistor field plate electrode 54 is formed in a ring shape in top view. The transistor field plate electrode 54 includes two main body parts 54A in a top view, located between the gate electrode 53 and the drain electrode 74, and connection portions 54B located on one side and the other side of the drain electrode 74 in the Y-axis direction such that the two adjacent main body portions 54A are connected to each other. The transistor field plate electrode 54 is formed in a ring shape surrounding the drain electrode 74. In one example, the transistor field plate electrode 54 is arranged inside the gate layer 51 and the gate electrode 53 formed in a ring shape. The gate layer 51 and the gate electrode 53 can be said to be formed so as to surround the transistor field plate electrode 54.

The transistor field plate electrode 54 is electrically connected to the source electrode 75. The nitride semiconductor device 10 may include a source connection portion 75B connected to the source electrode 75. In the transistor region 32, two source electrodes 75 are arranged sandwiching the annular gate electrode 53 in the X-axis direction. The source connection portion 75B is formed to extend in the X-axis direction and connects two source electrodes 75 arranged side by side in the X-axis direction. The source connection portion 75B is arranged at the same position as the connection portion 54B of the transistor field plate electrode 54 in the Y-axis direction. In a top view, the source connection portion 75B overlaps the connection portion 54B of the transistor field plate electrode 54. The source connection portion 75B is electrically connected to the connection portion 54B of the transistor field plate electrode 54 through the bonding via 57.

The anode layer 52 is provided separately from the gate electrode layer 51. The anode layer 52 is formed in a ring shape in the diode region 34 in a top view. The anode layer 52 includes two main body portions 52A, which are disposed sandwiching the cathode electrode 77 in the X-axis direction and extend in the Y-axis direction; and connection portions 52B located on one side and the other side of the cathode electrode 77 in the Y-axis direction such that two adjacent main body portions 52A are connected to each other. The anode layer 52 can be said to be formed in a ring shape surrounding the cathode electrode 77. The cathode electrode 77 can be said to be surrounded by the annular anode layer 52 in a top view.

The anode extending portion 76B is formed in an annular shape in the diode region 34 in a top view. In FIG. 4, the anode extending portion 76B includes two main body portions 76BA disposed sandwiching the cathode electrode 77 in the X-axis direction, and connection portions 76BB located on one side and the other side of the cathode electrode 77 in the Y-axis direction such that two adjacent main body portions 76BA are connected to each other.

As shown in FIGS. 2 and 4, the nitride semiconductor device 10 may include a source wiring 81 and a drain wiring 82. In FIGS. 2 and 4, the respective outer edges of the source wiring 81 and the drain wiring 82 are represented by one-dot chain lines. The source wiring 81 is electrically connected to the source pad 22 shown in FIG. 1. The drain wiring 82 is electrically connected to the drain pad 23 shown in FIG. 1. The source wiring 81 and the drain wiring 82 extend along the X-axis direction. The source wiring 81 and the drain wiring 82 are arranged in the Y-axis direction. The source wiring 81 and the drain wiring 82 are arranged to intersect the source electrode 75 and the drain electrode 74.

In one example, the drain electrode 74 and the drain wiring 82 are electrically connected through the bonding via 84. The cathode electrode 77 and the drain wiring 82 are electrically connected through the bonding via 83. The source electrode 75 and the source wiring 81 are electrically connected through the bonding via 85.

### (Method for Manufacturing Nitride Semiconductor Device)

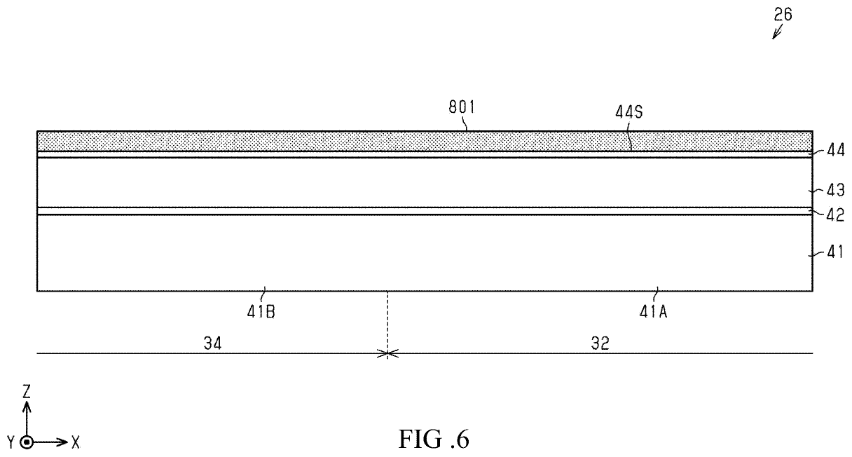

Next, an example of a method for manufacturing the nitride semiconductor device 10 in FIG. 1 will be described. FIGS. 6 to 15 are schematic cross-sectional views showing exemplary manufacturing steps of the nitride semiconductor device 10. FIGS. 6 to 15 correspond to the cross-sectional structure of the nitride semiconductor device 10 (the transistor 31 and the diode 33) shown in FIG. 5. In order to facilitate understanding, in FIGS. 6 to 15, the same components as those in FIGS. 4 and 5 are assigned the same reference numerals.

As shown in FIG. 6, the method for manufacturing the nitride semiconductor device 10 includes, for example, sequentially forming a buffer layer 42, an electron travelling layer 43, an electron supply layer 44, and a gallium nitride (GaN) layer 801 on a substrate 41, which serves as a Si substrate. The buffer layer 42, the electron travelling layer 43, the electron supply layer 44 and the GaN layer 801 can be epitaxially grown using a Metal Organic Chemical Vapor Deposition (MOCVD) method.

Detailed illustrations are omitted. In one example, the buffer layer 42 may be a multilayer buffer layer. The multilayer buffer layer may include an AlN layer (a first buffer layer) formed on the substrate 41 and a graded AlGaN layer (a second buffer layer) formed on the AlN layer. The graded AlGaN layer can be formed, for example, by sequentially stacking three AlGaN layers with Al compositions of 75%, 50%, and 25% from the side close to the AlN layer.

The electron travelling layer 43 formed on the buffer layer 42 may be a GaN layer. The electron supply layer 44 formed on the electron travelling layer 43 may be an AlGaN layer. Therefore, the electron supply layer 44 is composed of a nitride semiconductor having a larger band gap than the electron travelling layer 43.

The GaN layer 801 formed on the electron supply layer 44 may contain magnesium as an acceptor type impurity. By doping magnesium during growth of the GaN layer 801 on the electron supply layer 44, the GaN layer 801 containing acceptor-type impurities can be formed. The amount of magnesium doped in the GaN layer 801 can be adjusted, for example, by controlling the flow rate of the doping gas (e.g., dicyclopentadienylmagnesium (Cp2Mg)) introduced into the growth chamber, the growth temperature, and the like. In one example, the GaN layer 801 may contain magnesium as an impurity at a concentration between about 1×10¹⁸ cm⁻³ and about 1×10²⁰ cm⁻³.

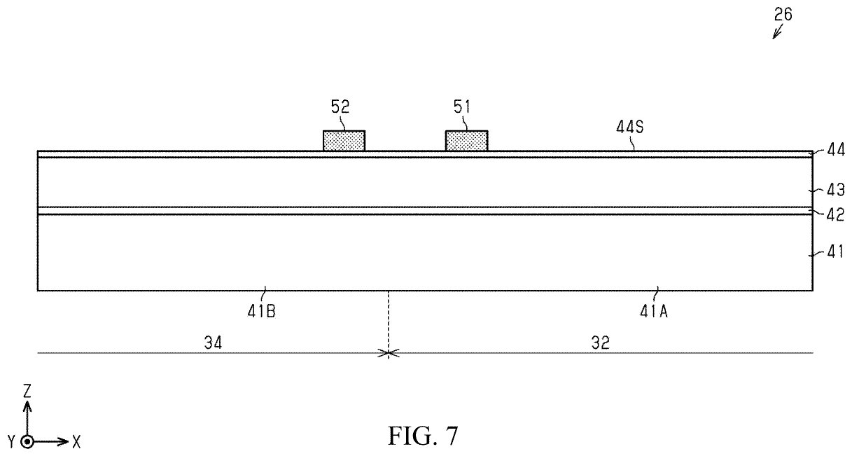

As shown in FIG. 7, the method for manufacturing the nitride semiconductor device 10 includes the steps of forming the gate layer 51 and the anode layer 52. The gate layer 51 and the anode layer 52 are formed by selectively removing the GaN layer 801 shown in FIG. 6. In one example, a mask layer is formed on the GaN layer 801 and covers the regions where the gate layer 51 and the anode layer 52 shown in FIG. 7 are formed. The mask layer is formed of, for example, a resist film. By selectively removing the GaN layer 801 using a mask layer, the gate layer 51 and the anode layer 52 shown in FIG. 7 are formed.

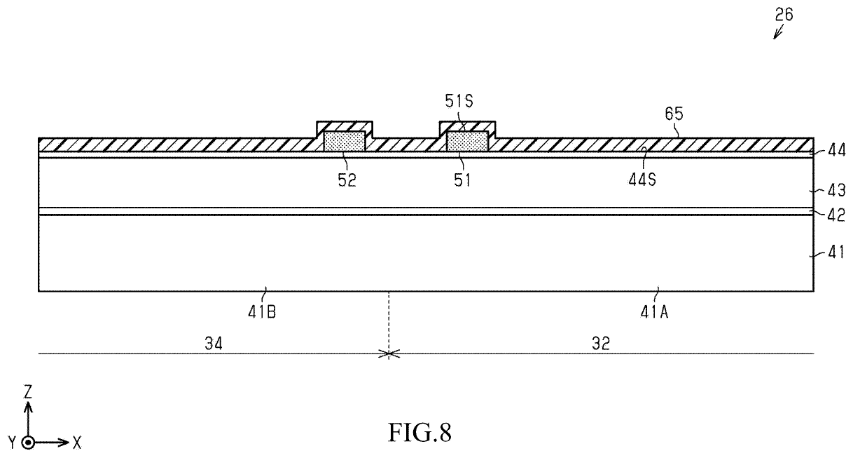

As shown in FIG. 8, the method for manufacturing the nitride semiconductor device 10 includes the step of forming the first passivation film 65. The first passivation film 65 covering the gate layer 51 and the anode layer 52 is formed on the electron travelling layer 43. In one example, the first passivation film 65 is an insulating film containing SiN. In one example, the first passivation film 65 can be formed by a Low Pressure Chemical Vapor Deposition (LPCVD) method.

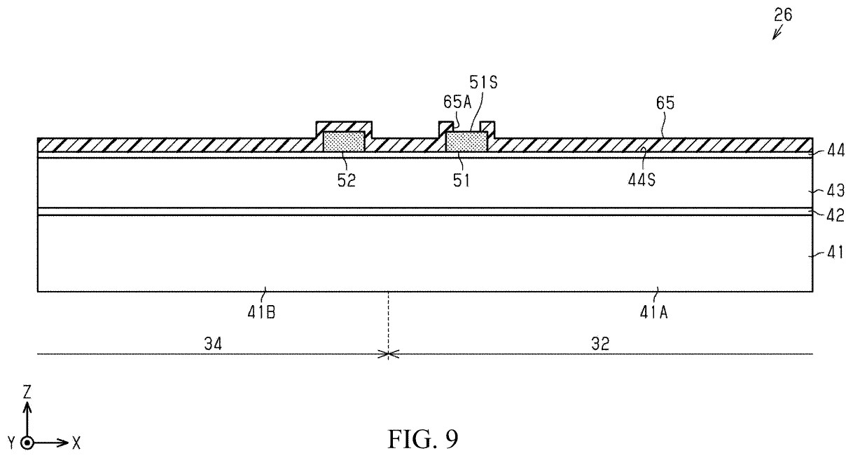

As shown in FIG. 9, the method for manufacturing the nitride semiconductor device 10 includes the step of forming the gate opening 65A. The gate opening 65A is formed by selectively removing the first passivation film 65 shown in FIG. 8. In one example, a mask layer including an opening exposing a region where the gate opening 65A shown in FIG. 9 is formed is formed on the first passivation film 65 shown in FIG. 8. In one example, the mask layer is formed of a resist film. By selectively removing the first passivation film 65 using the mask layer, the gate opening 65A shown in FIG. 9 is formed.

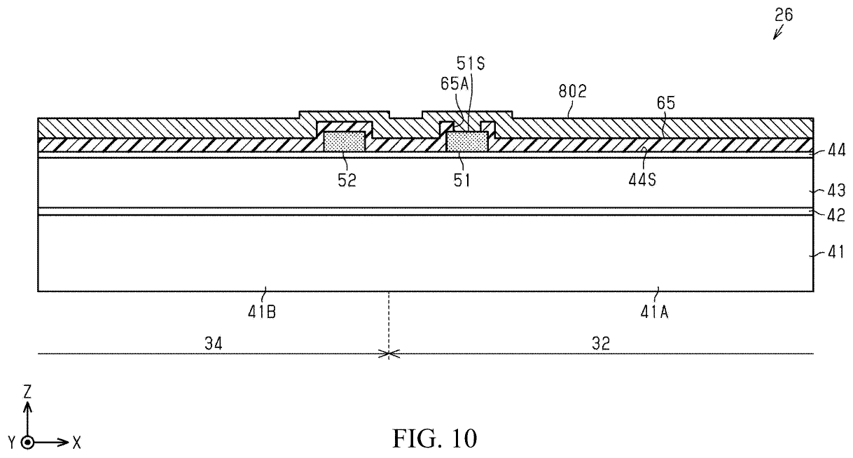

As shown in FIG. 10, the method for manufacturing the nitride semiconductor device 10 includes the step of forming a metal layer 802. The metal layer 802 is formed on the first passivation film 65. The metal layer 802 may be formed by sputtering in one example. The metal layer 802 may be formed of, for example, at least one material selected from a Ti layer, a TiCu layer, a TiN layer, an Al layer, an AlSiCu layer, and an AlCu layer. The metal layer 802 may be a TiN layer in one example. The metal layer 802 is in contact with the gate layer 51 within the gate opening 65A of the first passivation film 65.

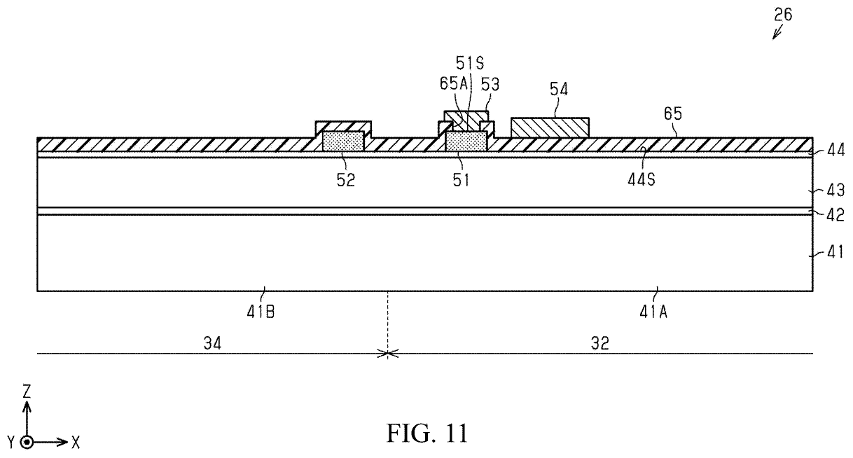

As shown in FIG. 11, the method for manufacturing the nitride semiconductor device 10 includes the steps of forming the gate electrode 53 and the transistor field plate electrode 54. The gate electrode 53 and the transistor field plate electrode 54 are formed by selectively removing the metal layer 802 shown in FIG. 10. In one example, a mask layer is formed on the metal layer 802 shown in FIG. 10, and the mask layer covers the regions where the gate electrode 53 and the transistor field plate electrode 54 are to be formed. Regarding the mask layer, in one example, the mask layer is formed of a resist film. By selectively removing the metal layer 802 using the mask layer, the gate electrode 53 and the transistor field plate electrode 54 shown in FIG. 11 are formed.

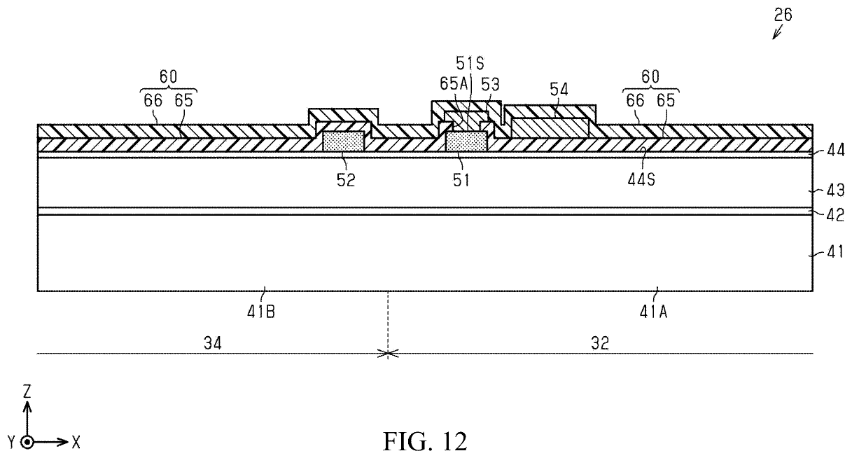

As shown in FIG. 12, the method for manufacturing the nitride semiconductor device 10 includes the step of forming the second passivation film 66. The second passivation film 66 covering the gate electrode 53 and the transistor field plate electrode 54 is formed on the first passivation film 65. The second passivation film 66 is an insulating film containing SiN in one example. In one example, the second passivation film 66 can be formed by a LPCVD method. The second passivation film 66 together with the first passivation film 65 constitutes the passivation layer 60.

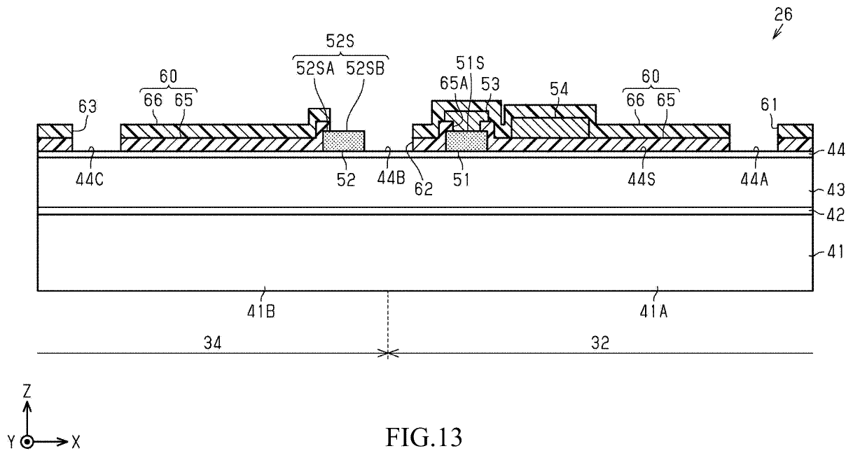

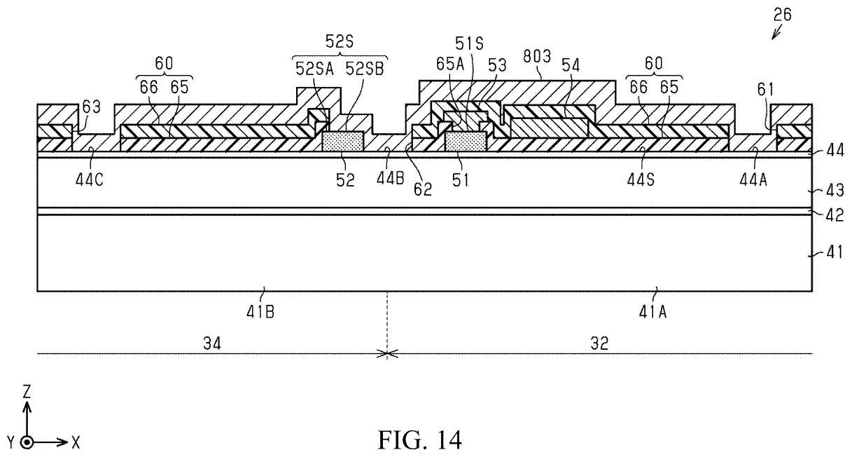

As shown in FIG. 13, the method for manufacturing the nitride semiconductor device 10 includes the step of forming the first opening 61, the second opening 62 and the third opening 63 in the passivation layer 60. The first opening 61, the second opening 62 and the third opening 63 can be formed by selectively removing the passivation layer 60. In one example, a mask layer is formed on the passivation layer 60, and the mask layer exposes the regions where the first opening 61, the second opening 62, and the third opening 63 shown in FIG. 14 are to be formed. In one example, the mask layer is formed of a resist film. By selectively removing the passivation layer 60 using the mask layer, the first opening 61, the second opening 62 and the third opening 63 shown in FIG. 14 are formed.

As shown in FIG. 14, the method for manufacturing the nitride semiconductor device 10 includes the step of forming a metal layer 803. The metal layer 803 covering the passivation layer 60 are formed to fill the first opening 61, the second opening 62 and the third opening 63. The metal layer 803 may be formed by sputtering in one example. The metal layer 803 may be formed of, for example, at least one material selected from a Ti layer, a TiCu layer, a TiN layer, an Al layer, an AlSiCu layer, and an AlCu layer. The metal layer 803 may be a TiCu layer in one example. The metal layer 803 is in contact with the electron travelling layer 43 in the first opening 61, the second opening 62 and the third opening 63 of the passivation layer 60. In addition, the metal layer 803 is in contact with the anode layer 52 in the second opening 62 of the passivation layer 60.

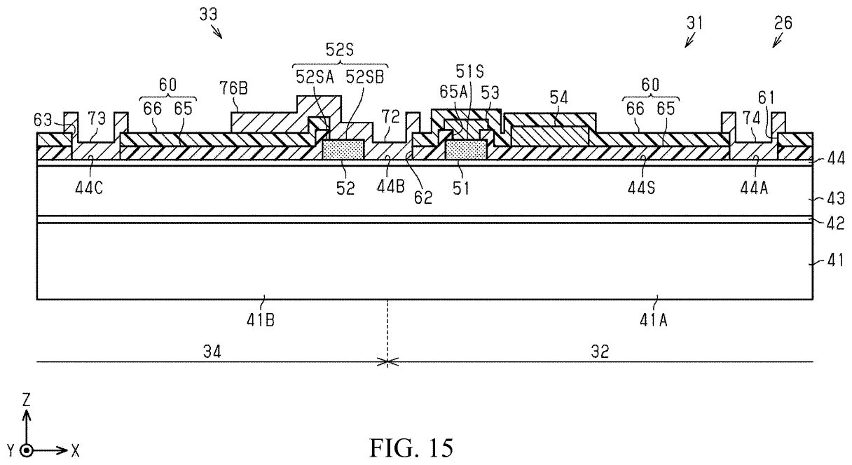

As shown in FIG. 15, the method for manufacturing the nitride semiconductor device 10 includes the steps of forming the first electrode 71, the second electrode 72, and the third electrode 73. The first electrode 71, the second electrode 72 and the third electrode 73 are formed by selectively removing the metal layer 803 shown in FIG. 14. In one example, a mask layer is formed on the metal layer 803 shown in FIG. 14, and the mask layer covers the region where the first electrode 71, the second electrode 72, and the third electrode 73 are to be formed. Regarding the mask layer, in one example, the mask layer is formed of a resist film. By selectively removing the metal layer 803 according to the mask layer, the first electrode 71, the second electrode 72, and the third electrode 73 shown in FIG. 15 are formed. The mask layer used in each stage is removed at appropriate time points. After the above steps, the nitride semiconductor device 10 shown in FIG. 5 can be obtained.

### (Effects)

As shown in FIG. 5, the nitride semiconductor device 10 includes an electron travelling layer 43 and an electron supply layer 44 formed on a substrate 41 in a state spanning both the transistor region 32 and the diode region 34. The gate layer 51 is formed on the electron supply layer 44 in the transistor region 32, and the anode layer 52 is formed on the electron supply layer 44 in the diode region. The nitride semiconductor device 10 includes a passivation layer 60 covering the electron supply layer 44, the gate layer 51, and the anode layer 52. The passivation layer 60 includes: a first opening 61 and a second opening 62, which are arranged to sandwich the gate layer 51 in the X-axis direction; and a third opening 63, which is connected to the first opening and the second opening in the X-axis direction. The openings 62 are separately arranged. The nitride semiconductor device 10 includes a first electrode 71 that is in contact with the electron supply layer 44 within the first opening 61, a second electrode 72 that is in contact with the electron supply layer 44 within the second opening 62, and a third electrode 73, in contact with the electron supply layer 44 in the third opening 63. The first electrode 71 is the drain electrode 74 formed in the transistor region 32, and the third electrode 73 is the cathode electrode 77 formed in the diode region 34. The second electrode 72 is in contact with both the electron supply layer 44 and the anode layer 52 exposed through the second opening 62, and serves as the source electrode 75 and the anode electrode 76.

A diode connected in reverse parallel to the transistor 31 is effective when the nitride semiconductor device 10 is used as a power device. In the usage of power devices, most of them are inductive loads. Therefore, when the power device is disconnected, the return current is required to flow from the source to the drain. In a power device using silicon as a semiconductor material, the structure of the device includes a body diode as a parasitic element, so the body diode plays a role in causing a return current to flow. However, in transistors using nitride semiconductors, parasitic elements such as body diodes are generally not included.

Consider incorporating GaN-SBD (Schottky Barrier Diode) into power devices using nitride semiconductors. However, GaN-SBD has a large leakage current, so there is a problem in practical use.

In the nitride semiconductor device, for example, it is conceivable to use a diode formed by short-circuiting the gate electrode 53 and the source electrode 75 of the transistor 31. The transistor 31 in which the gate electrode 53 and the source electrode 75 are short-circuited operates as a diode connected in reverse parallel to the other transistor 31. The ON voltage of the diode in which the source electrode 75 and the gate electrode 53 are short-circuited depends on the ON voltage of the transistor 31. Therefore, the transistor 31 functioning as a power device and functioning as a diode has a high conduction voltage during reverse conduction (for example, 2 to 3 V), so there is a problem that dead time loss becomes high. In this way, the transistor 31 in a state where the gate electrode 53 and the source electrode 75 are short-circuited has poor reverse conduction characteristics and may cause a large power loss.

On the other hand, in the nitride semiconductor device 10 of the first embodiment, the second electrode 72 serving as the anode electrode 76 is in contact with the anode layer 52. Therefore, the conduction voltage of diode 33 can be reduced. In this way, the diode 33 with a low forward voltage Vf can be formed. Therefore, the reverse conduction characteristics in the nitride semiconductor device 10 can be improved. Furthermore, it is possible to provide the nitride semiconductor device 10 which can improve the conduction characteristics of the source-drain current in the transistor 31. Therefore, it is possible to provide the nitride semiconductor device 10 with improved reverse conduction characteristics and improved electrical characteristics. In addition, it is possible to reduce power loss (dead time) when the nitride semiconductor device 10 of the first embodiment is used as a power device for a circuit that drives a capacitive load, such as a DC (direct current)/DC converter loss).

In addition, in this nitride semiconductor device 10, the second electrode 72 formed in the second opening 62 of the passivation layer 60 is shared by the transistor 31 and the diode 33. Therefore, the nitride semiconductor device 10 of the first embodiment can reduce the size of the chip body 11 compared to a nitride semiconductor device in which the source electrode 75 and the anode electrode 76 are separately arranged.

The nitride semiconductor device 10 includes the transistor field plate electrode 54 arranged between the gate layer 51 and the drain electrode 74 in the X-axis direction. Transistor field plate electrode 54 is electrically connected to source electrode 75. The transistor field plate electrode 54 plays a role in easing the electric field concentration in the drain-source region by extending the depletion layer toward the 2 DEG 45 directly below when a high voltage is applied to the drain electrode 74.

The passivation layer 60 includes a first passivation film 65 on the electron supply layer 44 and a second passivation film 66 on the first passivation film 65. The transistor field plate electrode 54 is formed on the first passivation film 65 and covered with the second passivation film 66. Therefore, components such as the transistor field plate electrode 54 can be easily arranged in the passivation layer 60.

The anode electrode 76 includes an anode extending portion 76B, which is provided in the diode region 34 and extends from the anode electrode 76 toward the cathode electrode 77. Anode extension 76B is formed on passivation layer 60. The anode electrode 76 and the source electrode 75 together constitute the second electrode 72. Therefore, the anode extending portion 76B and the source electrode 75 have the same potential. Therefore, similar to the transistor field plate electrode 54, the electric field concentration in the vicinity of the end portion of the anode layer 52 is reduced.

In the X-axis direction where the transistor region 32 and the diode region 34 are arranged, the length L34 of the diode region 34 is smaller than the length L32 of the transistor region 32. Therefore, compared with a case where the source and gate of the transistor formed on the chip body 11 are short-circuited and the transistor functions as a diode, an increase in the size of the nitride semiconductor device 10 in which the diode region 34 is formed can be suppressed.

The nitride semiconductor device 10 includes a first region 25 and a second region 26. The first region 25 includes only the transistor region 32 of the transistor region 32 and the diode region 34. The second region 26 includes both the transistor region 32 and the diode region 34. The transistor region ST, which is the total region of the transistor region 32 included in the first region 25 and the region of the transistor region 32 included in the second region 26, is larger than the region of the diode region 34 included in the second region 26. The total diode region SD. The ratio of the diode region SD to the total region S12 obtained by adding up the region S1 of the first region 25 and the region S2 of the second region 26 only needs to be less than 30%.

Increasing the region ratio of the diode region 34 increases the chip size or increases the on-resistance of the transistor 31. Therefore, by making the transistor region of the transistor region 32 larger than the diode region of the diode region 34, it is possible to suppress an increase in the on-resistance of the transistor 31 and reduce the on-voltage of the diode 33.

### (Effects)

As described above, according to the first embodiment, the following effects are achieved. (1-1) The nitride semiconductor device 10 includes: the electron travelling layer 43 formed on the substrate 41 in a state spanning both the transistor region 32 and the diode region 34 and composed of the nitride semiconductor; the electron supply layer 44 formed on the electron travelling layer 43 in a state spanning both the transistor region 32 and the diode region 34 and composed of the nitride semiconductor having a larger band gap than the electron travelling layer 43; the gate layer 51 formed on the electron supply layer 44 in the transistor region 32 and composed of the nitride semiconductor containing acceptor type impurities; and the passivation layer 60 covering the electron supply layer 44 and the gate layer 51. The passivation layer 60 includes: the first opening 61 and the second opening 62 arranged to sandwich the gate layer 51 in the X-axis direction; and the third opening 63 arranged to separate from the first opening 61 and the second opening 62 in the X-axis direction. The nitride semiconductor device 10 includes the first electrode 71 that is in contact with the electron supply layer 44 within the first opening 61, the second electrode 72 that is in contact with the electron supply layer 44 within the second opening 62, and the third electrode 73 that is in contact with the electron supply layer 44 in the third opening 63. Furthermore, the nitride semiconductor device 10 includes the anode layer 52 composed of the nitride semiconductor containing acceptor-type impurities. The second opening 62 is disposed at the boundary between the transistor region 32 and the diode region 34, and the second electrode 72 serves as both the source electrode 75 of the transistor 31 and the anode electrode 76 of the diode 33.

In the nitride semiconductor device 10 of the first embodiment, the second electrode 72 serving as the anode electrode 76 is in contact with the anode layer 52. Thus, the conduction voltage of the diode 33 can be reduced. In this way, the diode 33 with a low forward voltage Vf can be formed. Therefore, the reverse conduction characteristics in the nitride semiconductor device 10 can be improved. Furthermore, it is possible to provide the nitride semiconductor device 10 which can improve the conduction characteristics of the source-drain current in the transistor 31. Therefore, it is possible to provide the nitride semiconductor device 10 with improved reverse conduction characteristics and improved electrical characteristics.

(1-2) The nitride semiconductor device 10 uses the second electrode 72 formed in the second opening 62 of the passivation layer 60 in common for the transistor 31 and the diode 33. Therefore, the nitride semiconductor device 10 of the first embodiment can reduce the size of the chip body 11 compared to a nitride semiconductor device in which the source electrode 75 and the anode electrode 76 are separately arranged.

(1-3) The nitride semiconductor device 10 includes the transistor field plate electrode 54 arranged between the gate layer 51 and the drain electrode 74 in the X-axis direction. The transistor field plate electrode 54 is electrically connected to the source electrode 75. The transistor field plate electrode 54 plays a role in easing the electric field concentration in the drain-source region by extending the depletion layer toward the 2 DEG 45 directly below when a high voltage is applied to the drain electrode 74. As a result, dielectric breakdown of the electron supply layer 44 and the passivation layer 60 caused by localized electric field concentration can be suppressed, and the drain-source withstand voltage can be improved.

(1-4) The passivation layer 60 includes the first passivation film 65 on the electron supply layer 44 and the second passivation film 66 on the first passivation film 65. The transistor field plate electrode 54 is formed on the first passivation film 65 and covered with the second passivation film 66. Therefore, components such as the transistor field plate electrode 54 can be easily arranged in the passivation layer 60.

(1-5) The anode electrode 76 includes the anode extending portion 76B disposed in the diode region 34 and extending from the anode electrode 76 toward the cathode electrode 77. The anode extending portion 76B is formed on the passivation layer 60. The anode electrode 76 and the source electrode 75 together constitute the second electrode 72. Thus, the anode extending portion 76B and the source electrode 75 have the same potential. Therefore, similar to the transistor field plate electrode 54, the electric field concentration in the vicinity of the end portion of the anode layer 52 is reduced.

(1-6) In the X-axis direction in which the transistor region 32 and the diode region 34 are arranged, the length L34 of the diode region 34 is smaller than the length L32 of the transistor region 32. Therefore, compared with a case where the source and gate of the transistor formed on the chip body 11 are short-circuited and the transistor functions as a diode, an increase in the size of the nitride semiconductor device 10 in which the diode region 34 is formed can be suppressed.

(1-7) The nitride semiconductor device 10 includes the first region 25 and the second region 26. The first region 25 includes only the transistor region 32 among the transistor region 32 and the diode region 34. The second region 26 includes both the transistor region 32 and the diode region 34. The transistor area ST, which is the sum of the areas of the transistor regions 32 included in the first regions 25 and the areas of the transistor regions 32 included in the second regions 26, is larger than the diode area SD, which is the sum of the areas of the diode regions 34 included in the second regions 26. The ratio of the diode area SD to the total area S12 obtained by adding up the areas S1 of the first regions 25 and the areas S2 of the second regions 26 only needs to be less than 30%.

Increasing the area ratio of the diode region 34 increases the chip size or increases the on-resistance of the transistor 31. Therefore, by making the transistor area of the transistor region 32 larger than the diode area of the diode region 34, it is possible to suppress an increase in the on-resistance of the transistor 31 and reduce the on-voltage of the diode 33.

### Modified Examples of the First Embodiment

Hereinafter, modified examples of the nitride semiconductor device 10 of the first embodiment will be described. In addition, regarding the modified examples, the same components as those in the nitride semiconductor device 10 of the first embodiment are denoted by the same reference numerals.

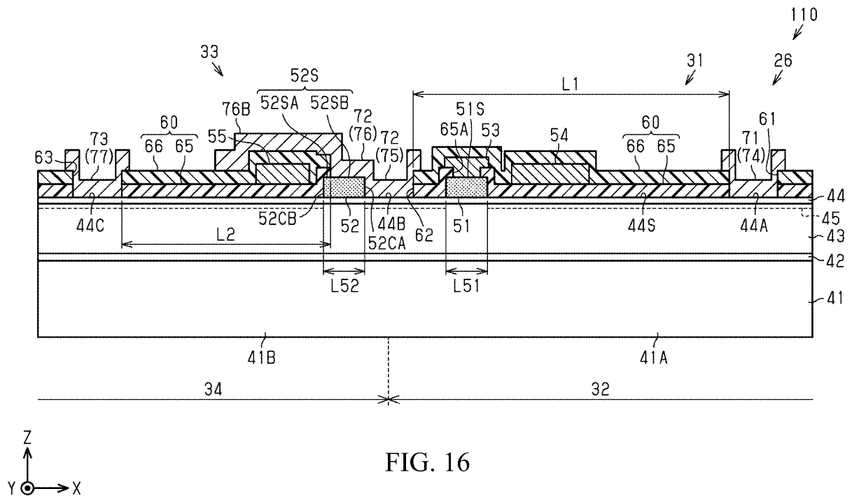

FIG. 16 shows a nitride semiconductor device 110 according to a modified example. The nitride semiconductor device 110 includes a diode field plate electrode 55. The diode field plate electrode 55 is arranged between the anode layer 52 and the third electrode 73 (the cathode electrode 77). In one example, the diode field plate electrode 55 is formed in a ring shape when viewed from above. The diode field plate electrode 55 is embedded in the passivation layer 60. The diode field plate electrode 55 is formed on the first passivation film 65 and covered with the second passivation film 66. In one example, the diode field plate electrode 55 is formed in a ring shape when viewed from above. The diode field plate electrode 55 is electrically connected to the anode electrode 76. In one example, the diode field plate electrode 55 may be formed through the same steps as the transistor field plate electrode 54.

The diode field plate electrode 55 electrically connected to the anode electrode 76 functions to relax the electric field concentration near the end of the anode layer 52 like the transistor field plate electrode 54.

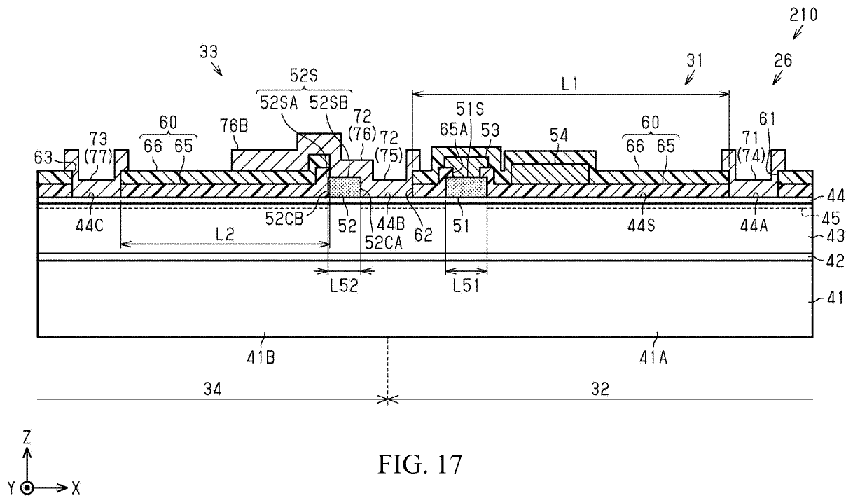

FIG. 17 shows a nitride semiconductor device 210 according to a modified example. In the X-axis direction, the length L52 of the anode layer 52 is different from the length L51 of the gate layer 51. In one example, the length L52 of the anode layer 52 is less than the length L51 of the gate layer 51. Thus, the length L34 (referring to FIG. 4) of the diode region 34 in the X-axis direction can be made smaller. Therefore, an increase in the chip size of the nitride semiconductor device 210 due to the inclusion of the diode region 34 can be suppressed.

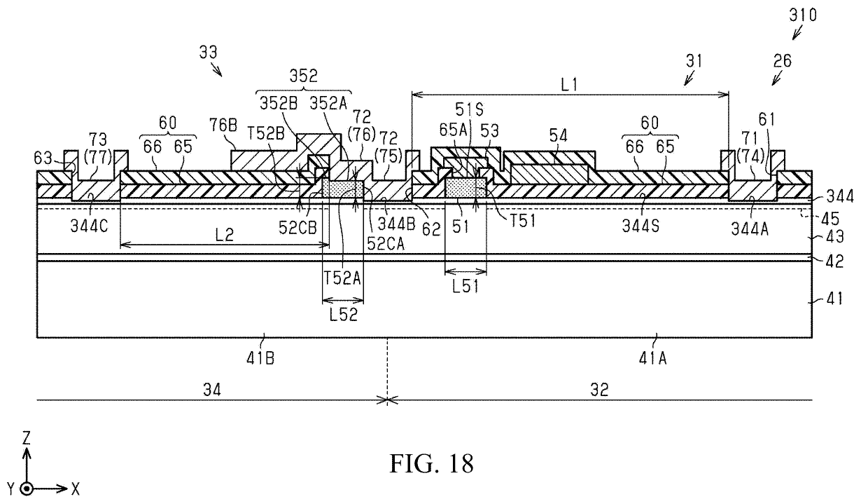

FIG. 18 shows a nitride semiconductor device 310 according to a modified example. The nitride semiconductor device 310 includes an anode layer 352. The anode layer 352 includes a second portion 352A having a film thickness T52A less than the film thickness T51 of the gate layer 51. In one example, the anode layer 352 may include a first portion 352B that has the same thickness as that of the gate layer 51 and a second portion 352A having a film thickness T52A less than the film thickness T51 of the gate layer 51. In addition, the thickness of the anode layer 352 may be the same between both ends in the X-axis direction. The first portion 352B of the anode layer 352 is covered by the passivation layer 60. The second portion 352A of the anode layer 352 is exposed through the second opening 62. The second portion 352A is in contact with the second electrode 72 (the anode electrode 76) formed in the second opening 62. This nitride semiconductor device 310 can further reduce the forward voltage Vf of the diode 33. Therefore, the conduction voltage of diode 33 can be further reduced.

In addition, the electron supply layer 344 of the nitride semiconductor device 310 includes recessed portions 344A, 344B, and 344C formed on the upper surface 344S. The recessed portions 344A, 344B, and 344C are formed in the regions of the electron supply layer 344 exposed through the first opening 61, the second opening 62, and the third opening 63 of the passivation layer 60 respectively. The bottom surface and side surfaces forming the recessed portion 344A constitute the first connection region. The bottom surface and side surfaces forming the recessed portion 344B constitute the second connection region. The bottom surface and side surfaces forming the recessed portion 344C constitute the third connection region. The first electrode 71, the second electrode 72, and the third electrode 73 are filled in the recessed portions 344A, 344B, and 344C formed in the electron supply layer 344. Thus, the ohmic resistance between each of the first electrode 71, the second electrode 72, and the third electrode 73 and the 2 DEG 45 can be reduced. Therefore, the on-resistance of the transistor 31 can be reduced. In addition, the on-resistance of the diode 33 can be reduced.

### Second Embodiment

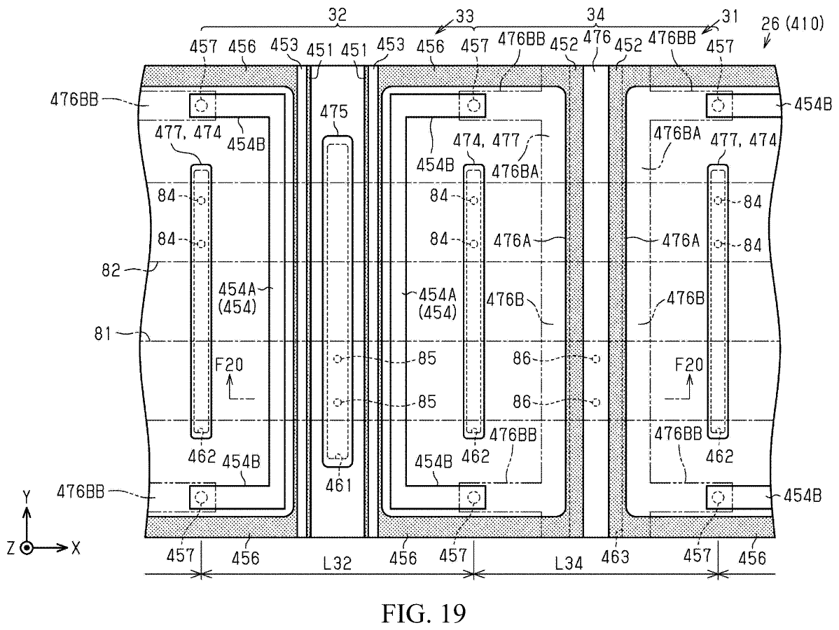

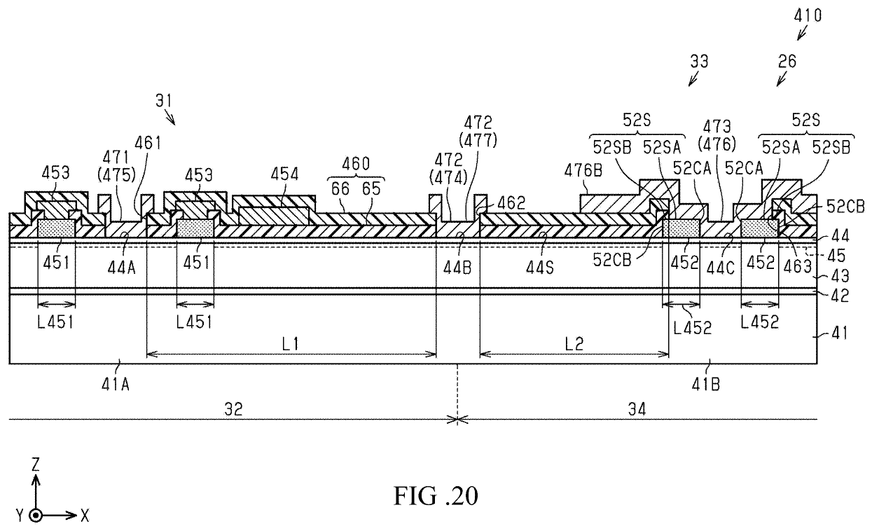

FIG. 19 is an enlarged schematic top view of a portion of a nitride semiconductor device 410 of the second embodiment, more specifically, a portion of the second region 26. FIG. 20 is a schematic cross-sectional view of the nitride semiconductor device 410 taken along line F20-F20 in FIG. 19. In FIGS. 19 and 20, the same components as those in the nitride semiconductor device 10 of the first embodiment are denoted by the same reference numerals.

Compared with the nitride semiconductor device 10 of the first embodiment, the nitride semiconductor device 410 of the second embodiment differs mainly in the shape of the first to third electrodes 471 to 473 and that the second electrode 472 is a drain electrode and also a cathode.

As shown in FIG. 20, the nitride semiconductor device 410 includes a substrate 41, a buffer layer 42 formed on the substrate 41, an electron travelling layer 43 formed on the buffer layer 42, and an electron supply layer formed on the electron travelling layer 43. 44.

The nitride semiconductor device 410 further includes a gate layer 451 and an anode layer 452 formed on the electron supply layer 44, a gate electrode 453 formed on the gate layer 451 and a passivation layer 460.

### (Passivation Layer)

The passivation layer 460 is formed to cover the electron supply layer 44, the gate layer 451, the gate electrode 453 and the anode layer 452. In one example, the passivation layer 460 is in contact with the electron supply layer 44, the gate layer 451, the gate electrode 453 and the anode layer 452.

The passivation layer 460 includes a first opening 461, a second opening 462, and a third opening 463. The first opening 461 and the second opening 462 are arranged with the gate layer 451 sandwiched therebetween. The first opening 461 and the second opening 462 are separated from the gate layer 451. The distance between the first opening 461 and the gate layer 451 is less than the distance between the second opening 462 and the gate layer 451. It can be said that the first opening 461 is formed closer to the gate layer 451 than the second opening 462. It can be said that the gate layer 451 is arranged closer to the first opening 461 than the second opening 462.

The third opening 463 is arranged apart from the first opening 461 and the second opening 462 in the X-axis direction. The third opening 463 is arranged on the opposite side to the first opening 461 with respect to the second opening 462.

The second opening 462 is provided at the boundary between the transistor region 32 and the diode region 34. The first opening 461 is provided in the transistor region 32. In one example, the first opening 461 is provided at the center of the transistor region 32 in the X-axis direction. The third opening 463 is provided in the diode region 34. In one example, the third opening 463 is provided at the center of the diode region 34 in the X-axis direction. As shown in FIG. 4, the first opening 461, the second opening 462, and the third opening 463 are formed to extend in the Y-axis direction.

The first opening 461 is formed to expose a portion of the upper surface 44S of the electron supply layer 44. The first opening 461 exposes the upper surface 44S of the electron supply layer 44 as the first connection region 44A. In the nitride semiconductor device 410 of the second embodiment, two gate electrode layers 451 are arranged adjacent to each other in the X-axis direction. The first opening 461 is spaced apart from the two gate layers 451 and is arranged between the two gate layers 451. Furthermore, the first opening 461 exposes the upper surface of the electron supply layer 44 between the two gate layers 451 as a first connection region. The second opening 462 is formed to expose a portion of the upper surface 44S of the electron supply layer 44. The second opening 462 exposes the upper surface 44S of the electron supply layer 44 as the second connection region 44B.

The third opening 463 is formed to expose a portion of the upper surface 44S of the electron supply layer 44. The third opening 463 exposes the upper surface 44S of the electron supply layer 44 as the third connection region 44C. In the nitride semiconductor device 410 of the second embodiment, two anode layers 452 are arranged adjacent to each other in the X-axis direction. The third opening 463 is formed to expose two adjacent anode layers 452. In one example, the length L452 of the anode layer 452 in the X-axis direction is equal to the length L451 of the gate layer 451 in the X-axis direction.

The anode layer 452 includes the upper surface 52S and the side surfaces 52CA and 52CB. The upper surface 52S of the anode layer 452 faces the same direction as the upper surface 44S of the electron supply layer 44. The side surfaces 52CA and 52CB face opposite sides to each other in the X-axis direction. The side surfaces 52CA of the two anode layers 452 face each other. The side surface 52CB of the anode layer 452 faces the second opening 462 side. The third opening 463 of the passivation layer 460 is formed to expose the mutually opposing side surfaces 52CA of the two anode layers 452 and to expose the portions 52SA of the upper surfaces 52S of the anode layers 452 on the sides close to the mutually opposing side surfaces 52CA.

### (First Electrode, Second Electrode, Third Electrode)

The nitride semiconductor device 410 includes a first electrode 471, a second electrode 472, and a third electrode 473. The first electrode 471 is in contact with the first connection region 44A of the electron supply layer 44 within the first opening 461. The first electrode 471 is in ohmic contact with 2 DEG 45 directly below the electron supply layer 44 via the electron supply layer 44. The second electrode 472 is in contact with the second connection region 44B of the electron supply layer 44 within the second opening 462. The second electrode 472 is in ohmic contact with the 2 DEG 45 directly below the electron supply layer 44 via the electron supply layer 44. The third electrode 473 is in contact with the third connection region 44C of the electron supply layer 44 in the third opening 463. The third electrode 473 is in ohmic contact with the 2 DEG 45 directly below the electron supply layer 44 via the electron supply layer 44. The nitride semiconductor device 410 can be said to include the first electrode 471 in contact with the electron supply layer 44 in the first opening 461, the second electrode 472 in contact with the electron supply layer 44 in the second opening 462, and the third electrode 473 in contact with the electron supply layer 44 in the third opening 463. It can be said that the first electrode 471, the second electrode 472 and the third electrode 473 are formed of a material that is in ohmic contact with the electron supply layer 44. The third opening 463 is formed to expose the anode layer 452. Therefore, the third electrode 473 is in contact with the anode layer 452 exposed through the third opening 463. The third electrode 473 is in ohmic contact with the anode layer 452. The third electrode 473 may be formed of a material that is in ohmic contact with the anode layer 452.

The first electrode 471 is a source electrode formed in the transistor region 32. The second electrode 472 is provided at the boundary between the transistor region 32 and the diode region 34 and serves as a drain electrode and also a cathode electrode. The third opening 463 is provided at a position opposite to the first electrode 471 and separated in the X-axis direction with respect to the second electrode 472 in the diode region 34 to expose the electron supply layer 44 and the anode layer 452. The third electrode 473 is an anode electrode in contact with both the electron supply layer 44 and the anode layer 452. In the following description, the first electrode 471 may be described as the source electrode 475, the third electrode 473 may be described as the anode electrode 476, and the second electrode 472 may be described as the drain electrode 474 or the cathode electrode 477.

The distance L1 between the first opening 461 and the second opening 462 in the transistor region 32 corresponds to the drain-source distance of the transistor 31. The distance L2 between the second opening 462 and the third opening 463 in the diode region 34 corresponds to the anode-cathode distance of the diode 33. The distance L2 in the diode region 34 is shorter than the distance L1 in the transistor region 32.

The anode electrode 476 may include an anode extending portion 476B. In one example, the anode electrode 476 includes an anode electrode portion 476A and the anode extending portion 476B that is continuous with the anode electrode portion 476A. The anode electrode portion 476A includes a portion in contact with the electron travelling layer 43 and the anode layer 452. The anode extending portion 476B may be integrally formed with the anode electrode portion 476A. The anode extending portion 476B is disposed in the diode region 34. The anode extending portion 476B extends from the anode layer 452 toward the cathode electrode 477.

The nitride semiconductor device 410 includes a transistor field plate electrode 454. The transistor field plate electrode 454 is provided on the electron supply layer 44 in the transistor region 32 and between the gate layer 451 and the drain electrode 474. The transistor field plate electrode 454 is embedded in the passivation layer 460. Specifically, the transistor field plate electrode 454 is disposed on the first passivation film 65 and covered by the second passivation film 66.

### (Planar Structure of Transistor Region and Diode Region)

As shown in FIG. 19, the nitride semiconductor device 410 includes the gate layer 451 and the anode layer 452 arranged to sandwich the drain electrode 474 (the cathode electrode 477) in the X-axis direction. The nitride semiconductor device 410 includes two connection wires 456 that connect the gate layer 451 and the anode layer 452. The two connection wires 456, the gate layer 451, and the anode layer 452 are connected in a ring shape. The nitride semiconductor device 410 can be said to include a ring-shaped wiring composed of the gate layer 451, the anode layer 452, and the two connection wires 456.

The transistor field plate electrode 454 is electrically connected to the anode electrode 476. In one example, the transistor field plate electrode 454 and the anode electrode 476 are connected through respective connection portions 454B and 476BB. The transistor field plate electrode 454 includes a main body portion 454A disposed between the gate layer 451 and the drain electrode 474 and a connection portion 454B extending from the main body portion 454A in the opposite direction to the gate layer 451. The connection portion 454B can be said to extend from the main body portion 454A toward the diode region 34. The anode extending portion 476B includes a main body portion 476BA arranged in the third opening 463 and a connection portion 476BB extending from the main body portion 476BA toward the transistor region 32. The anode electrode 476 can be said to include the connection portion 476BB. The connection portion 454B of the transistor field plate electrode 454 and the connection portion 476BB of the anode electrode 476 are electrically connected through the bonding via 457. In one example, the bonding via 457 is located at the boundary between the transistor region 32 and the diode region 34.

As shown in FIG. 19, the nitride semiconductor device 410 may include a source wiring 81 and a drain wiring 82. In FIG. 19, the respective outer edges of the source wiring 81 and the drain wiring 82 are indicated by dashed-dotted lines. The source wiring 81 is electrically connected to the source pad 22 shown in FIG. 1. The drain wiring 82 is electrically connected to the drain pad 23 shown in FIG. 1. The source wiring 81 and the drain wiring 82 extend along the X-axis direction. The source wiring 81 and the drain wiring 82 are arranged in the Y-axis direction. The source wiring 81 and the drain wiring 82 are arranged to intersect the source electrode 475 and the drain electrode 474.

In one example, the drain electrode 474 and the drain wiring 82 are electrically connected through the bonding via 84. The source electrode 475 and the source wiring 81 are electrically connected through the bonding via 85. The anode electrode 476 and the source wiring 81 are electrically connected through the bonding via 86.

### (Effects)

As described above, according to the second embodiment, the following effects are achieved. (2-1) The same effects as those of the nitride semiconductor device 10 of the first embodiment are achieved.

(2-2) The third electrode 473 is the anode electrode 476 in contact with both the anode layer 452 and the electron supply layer 44. In the nitride semiconductor device 410 of the second embodiment, two anode layers 452 are provided with the electron supply layer 44 sandwiched therebetween. Thus, even if the length of the electron supply layer 44 in the X-axis direction is reduced, it can still function as the anode electrode 476. Therefore, the length L34 of the diode region 34 in the X-axis direction can be reduced. Furthermore, the chip size of the nitride semiconductor device 410 can be reduced.

### MODIFIED EXAMPLES

The above-described embodiments can be modified as follows, for example. The above-described embodiments and the following modified examples may be combined with each other as long as no technical contradiction occurs. In addition, in the following modified examples, the same reference numerals as those in the above-described embodiments are assigned to the parts that are common to the above-described embodiments, and the description thereof is omitted.
The arrangement position, size, shape, quantity, etc. of the first region 25 and the second region 26 shown in FIG. 1 can be changed arbitrarily.

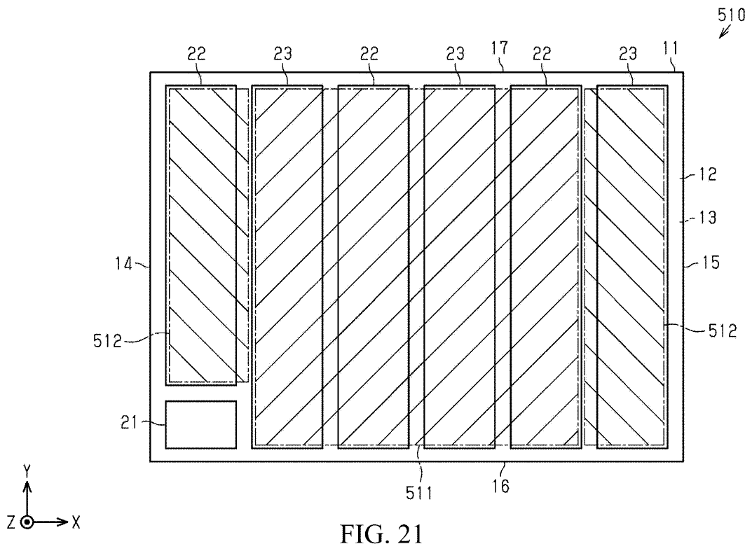

As shown in FIG. 21, in the nitride semiconductor device 510 of the modified example, two second regions 512 are arranged at both ends in the X-axis direction respectively, and a first region 511 is arranged between the two second regions 512. The first region 511 and the second region 512 are each formed in a rectangular shape.

The first region 511 may be disposed at both ends in the Y-axis direction, or may be disposed at the center of the nitride semiconductor device 510 in the Y-axis direction.

In addition, a plurality of the first regions 511 and a plurality of the second regions 512 may also be arranged alternately with respect to at least one of the X-axis direction and the Y-axis direction.

In addition, the second region 512 may be surrounded by the first region 511, and the first region 511 may be formed in a ring shape surrounding the second region 512. In addition, the first region 511 may be surrounded by the second region 512, and the second region 512 may be formed in a ring shape surrounding the first region 511.
The nitride semiconductor device 10 of the first embodiment may include a cathode pad electrically connected to the drain pad 23. The nitride semiconductor device 410 of the second embodiment may include an anode pad electrically connected to the source pad 22.

The term “on” used in the present disclosure includes both “on” and “above” as long as it does not mean something that is obviously not the case based on the context. Therefore, the expression “the first layer is formed on the second layer” is intended to mean that in a certain embodiment the first layer may be in contact with the second layer and directly disposed on the second layer, but in other embodiments the first layer may be placed above the second layer without contacting the second layer. In other words, the term “on” does not exclude the structure in which other layer is formed between the first layer and the second layer.

The Z-axis direction used in the present disclosure does not necessarily have to be the vertical direction, nor does it need to be completely consistent with the vertical direction. Therefore, regarding various structures of the present disclosure (for example, the structure shown in FIG. 1), the “upper” and “lower” in the Z-axis direction described in this specification are not limited to the “upper” and “lower” in the vertical direction. For example, the X-axis direction may be the vertical direction, or the Y-axis direction may be the vertical direction.

### (Note)

The technical ideas that can be understood from this disclosure are described below. Note that, not for the purpose of limitation but for the purpose of aiding understanding, the reference numerals of the corresponding components in the embodiments are attached to the components described in supplementary notes. Reference numerals are shown by way of example to aid understanding, and the components described in each appendix should not be limited to the components indicated by the reference numerals.

### (Note 1)

A nitride semiconductor device, comprising:
a substrate (41), having a transistor region (32) including a transistor (31), and a diode region (34) including a diode (33), wherein the diode region (34) is disposed adjacent to the transistor region (32) along a first direction (X);
a first nitride semiconductor layer (43), formed on the substrate (41) across both the transistor region (32) and the diode region (34), and made of a nitride semiconductor;
a second nitride semiconductor layer (44), formed on the first nitride semiconductor layer (43) across both the transistor region (32) and the diode region (34), and made of a nitride semiconductor having a band gap greater than a band gap of the first nitride semiconductor layer (43);
a gate layer (51, 451), formed on the second nitride semiconductor layer (44) in the transistor region (32) and made of a nitride semiconductor containing acceptor-type impurities;
a gate electrode (53, 453), formed on the gate layer (51, 451);
a passivation layer (60), covering the second nitride semiconductor layer (44), the gate layer (51, 451) and the gate electrode (53, 453), and including:
   a first opening (61, 461) and a second opening (62, 462), arranged to sandwich the gate layer (51, 451) along the first direction (X); and
   a third opening (63, 463) arranged apart from the first opening (61, 461) and the second opening (62, 462) along the first direction (X);
a first electrode (71, 471), in contact with the second nitride semiconductor layer (44) within the first opening (61, 461);
a second electrode (72, 472), in contact with the second nitride semiconductor layer (44) within the second opening (62, 462);
a third electrode (73, 473), in contact with the second nitride semiconductor layer (44) within the third opening (63, 463); and
an anode layer (52, 452), formed on the second nitride semiconductor layer (44) in the diode region (34) and made of a nitride semiconductor containing acceptor-type impurities, wherein
the second opening (62) is disposed at a boundary between the transistor region (32) and the diode region (34), and the second electrode (72) is used as both an electrode of the transistor (31) and an electrode of the diode (33).

### (Note 2)

The nitride semiconductor device of Note 1, wherein
the first electrode (71) is a drain electrode (74) formed in the transistor region (32),
the third electrode (73) is a cathode electrode (77) disposed at a position opposite to the first electrode (71) with respect to the second electrode (72) in the diode region (34) and separated along the first direction (X),
the second opening (62) exposes the second nitride semiconductor layer (44) and the anode layer (52), and
the second electrode (72) is in contact with both the second nitride semiconductor layer (44) and the anode layer (52), and is both a source electrode (75) and an anode electrode (76).

### (Note 3)

The nitride semiconductor device of Note 1, wherein
the first electrode (471) is a source electrode (475) formed in the transistor region (32),
the second electrode (472) is both a drain electrode (474) and a cathode electrode (477),
the third opening (463) is disposed at a position opposite to the first electrode (471) from the second electrode (472) in the diode region (34) and spaced apart along the first direction (X), wherein the third opening (463) exposes the second nitride semiconductor layer (44) and the anode layer (452), and
the third electrode (473) is an anode electrode (476) that is in contact with both the second nitride semiconductor layer (44) and the anode layer (52).

### (Note 4)

The nitride semiconductor device of Note 2 or 3, wherein the anode electrode (76, 476) includes an anode extending portion (76B, 476B) disposed in the diode region (34) and extending from the anode layer (52) toward the cathode electrode (77, 477).

### (Note 5)

The nitride semiconductor device of Note 4, including a diode field plate electrode (55),
embedded within the passivation layer (60) and between the anode layer (52) and the cathode electrode (77) in the diode region (34), and
electrically connected to the anode electrode (76), wherein
the anode extending portion (76B) is on the passivation layer (60) and extends toward the cathode electrode (77) from the diode field plate electrode (55).

### (Note 6)

The nitride semiconductor device of Note 5, wherein
the passivation layer (60) includes a stacked first passivation film (65) and a second passivation film (66),
the diode field plate electrode (55) is formed on the first passivation film (65),
the second passivation film (66) covers the diode field plate electrode (55), and
the anode extending portion (76B) is formed on the second passivation film (66).

### (Note 7)

The nitride semiconductor device of any one of Notes 2 to 6, including a transistor field plate electrode (54),
disposed on the second nitride semiconductor layer (44) in the transistor region (32), and between the gate layer (51) and the drain electrode, and
electrically connected to the source electrode.

### (Note 8)

The nitride semiconductor device of Note 7, wherein
the passivation layer (60) includes a first passivation film (65) and a second passivation film (66), and
the transistor field plate electrode (54) is disposed on the first passivation film (65) and covered with the second passivation film (66).

### (Note 9)

The nitride semiconductor device of any one of Notes 2 to 8, wherein a length of the anode layer (52) along the first direction (X) is less than a length of the gate layer (51) along the first direction (X).

### (Note 10)

The nitride semiconductor device of any one of Notes 2 to 9, wherein a distance between the anode layer (52) and the cathode electrode (77) along the first direction (X) is less than a distance between the gate layer (51) and the drain electrode along the first direction (X).

### (Note 11)

11. The nitride semiconductor device of any one of Notes 2 to 10, wherein the gate electrode (53) and the anode electrode (76) are made of a material for forming a Schottky contact or a material for forming an ohmic contact.

### (Note 12)

The nitride semiconductor device of any one of Notes 2 to 11, wherein a thickness of the anode layer (52) is less than a thickness of the gate layer (51).

### (Note 13)

The nitride semiconductor device of Note 2, wherein
the anode layer (52) includes a first side surface (52CB) and a second side surface (52CA) facing opposite to each other along the first direction (X), and
the first side surface (52CB) is covered with the passivation layer (60), and the second side surface (52CA) is exposed through the second opening (62).

### (Note 14)

The nitride semiconductor device of Note 3, wherein
the anode layer (452) includes a first side surface (52CB) and a second side surface (52CA) facing opposite to each other along the first direction (X), and
the first side surface (52CB) is covered with the passivation layer (60), and the second side surface (52CA) is exposed through the third opening (63).

### (Note 15)

The nitride semiconductor device of any one of Notes 2 to 14, wherein the anode layer (352) includes a portion having a thickness less than a thickness of the gate layer (51).

### (Note 16)

The nitride semiconductor device of any one of Notes 2 to 14, wherein the anode layer (352) includes a first portion (352B) having a thickness equal to a thickness of the gate layer (51), and a second portion (352A) having a thickness less than the thickness of the gate layer (51).

### (Note 17)

The nitride semiconductor device of Note 16, wherein the first portion (352B) is covered by the passivation layer (60), and the second portion (352A) is exposed through the second opening (62).

### (Note 18)

The nitride semiconductor device of any one of Notes 2 to 17, wherein the diode region (34) is smaller than the transistor region (32).

### (Note 19)

The nitride semiconductor device of any one of Notes 2 to 18, wherein a distance between the second opening (62) and the third opening (63) is less than a distance between the first opening (61) and the second opening (62).

### (Note 20)

The nitride semiconductor device of any one of Notes 2 to 19, wherein
the gate layer (51) is formed in an annular shape when viewed from a thickness direction of the substrate (41) in the transistor region (32),
the drain electrode is surrounded by the gate layer (51) when viewed from the thickness direction of the substrate (41),
the anode layer (52) is disposed apart from the gate layer (51) and formed in an annular shape when viewed from the thickness direction of the substrate (41) in the diode region (34),
the cathode electrode (77) is surrounded by the anode layer (52) when viewed from the thickness direction of the substrate (41).

### (Note 21)

The nitride semiconductor device of any one of Notes 3 to 20, including:
a connection portion (456) connecting the gate layer (451) and the anode layer (452), wherein
the gate layer (451), the anode layer (452) and the connection portion (456) are formed in an annular shape.

### (Note 22)

The nitride semiconductor device of any one of Notes 1 to 21, including:
a first region (25) in which only the transistor region (32) of the transistor region (32) and the diode region (34) is formed; and
a second region (26) in which both the transistor region (32) and the diode region (34) are formed, wherein
a transistor area, which is a sum of areas of the plurality of transistor regions (32) included in the first region (25) and the second region (26), is greater than a diode area of the plurality of diode regions (34) included in the second region (26).

### (Note 23)

The nitride semiconductor device of Note 22, wherein a ratio of the diode area to the sum of the areas of the first region (25) and the second region (26) is less than 30%.

### (Note 24)

The nitride semiconductor device of Note 22 or 23, wherein in the second region (26), the transistor region (32) and the diode region (34) are alternately arranged along the first direction (X).

The above description is merely illustrative. Those skilled in the art will recognize that many more possible combinations and permutations are possible beyond those listed for the purpose of describing the techniques of the present disclosure. This disclosure is intended to cover all alternatives, variations, and modifications falling within the scope of this disclosure, including the claims.

1. A nitride semiconductor device, comprising:
a substrate, having a transistor region including a transistor, and a diode region including a diode, wherein the diode region is disposed adjacent to the transistor region along a first direction;
a first nitride semiconductor layer, formed on the substrate across both the transistor region and the diode region, and made of a nitride semiconductor;
a second nitride semiconductor layer, formed on the first nitride semiconductor layer across both the transistor region and the diode region, and made of a nitride semiconductor having a band gap greater than a band gap of the first nitride semiconductor layer;
a gate layer, formed on the second nitride semiconductor layer in the transistor region and made of a nitride semiconductor containing acceptor-type impurities;
a gate electrode, formed on the gate layer;
a passivation layer, covering the second nitride semiconductor layer, the gate layer and the gate electrode, and including:
a first opening and a second opening, arranged to sandwich the gate layer along the first direction; and
a third opening arranged apart from the first opening and the second opening along the first direction;
a first electrode, in contact with the second nitride semiconductor layer within the first opening;
a second electrode, in contact with the second nitride semiconductor layer within the second opening;
a third electrode, in contact with the second nitride semiconductor layer within the third opening; and
an anode layer, formed on the second nitride semiconductor layer in the diode region and made of a nitride semiconductor containing acceptor-type impurities, wherein
the second opening is disposed at a boundary between the transistor region and the diode region, and the second electrode is used as both an electrode of the transistor and an electrode of the diode.

2. The nitride semiconductor device of claim 1, wherein
the first electrode is a drain electrode formed in the transistor region,
the third electrode is a cathode electrode disposed at a position opposite to the first electrode with respect to the second electrode in the diode region and separated along the first direction,
the second opening exposes the second nitride semiconductor layer and the anode layer, and
the second electrode is in contact with both the second nitride semiconductor layer and the anode layer, and is both a source electrode and an anode electrode.

3. The nitride semiconductor device of claim 1, wherein
the first electrode is a source electrode formed in the transistor region,
the second electrode is both a drain electrode and a cathode electrode,
the third opening is disposed at a position opposite to the first electrode from the second electrode in the diode region and spaced apart along the first direction, wherein the third opening exposes the second nitride semiconductor layer and the anode layer, and
the third electrode is an anode electrode that is in contact with both the second nitride semiconductor layer and the anode layer.

4. The nitride semiconductor device of claim 2, wherein the anode electrode includes an anode extending portion disposed in the diode region and extending from the anode layer toward the cathode electrode.

5. The nitride semiconductor device of claim 4, including a diode field plate electrode,
embedded within the passivation layer and between the anode layer and the cathode electrode in the diode region, and
electrically connected to the anode electrode, wherein
the anode extending portion is on the passivation layer and extends toward the cathode electrode from the diode field plate electrode.

6. The nitride semiconductor device of claim 5, wherein
the passivation layer includes a stacked first passivation film and a second passivation film,
the diode field plate electrode is formed on the first passivation film,
the second passivation film covers the diode field plate electrode, and
the anode extending portion is formed on the second passivation film.

7. The nitride semiconductor device of claim 2, including a transistor field plate electrode,
disposed on the second nitride semiconductor layer in the transistor region, and between the gate layer and the drain electrode, and
electrically connected to the source electrode.

8. The nitride semiconductor device of claim 7, wherein
the passivation layer includes a first passivation film and a second passivation film, and
the transistor field plate electrode is disposed on the first passivation film and covered with the second passivation film.

9. The nitride semiconductor device of claim 2, wherein a length of the anode layer along the first direction is less than a length of the gate layer along the first direction.

10. The nitride semiconductor device of claim 2, wherein a distance between the anode layer and the cathode electrode along the first direction is less than a distance between the gate layer and the drain electrode along the first direction.

11. The nitride semiconductor device of claim 2, wherein the gate electrode and the anode electrode are made of a material for forming a Schottky contact or a material for forming an ohmic contact.

12. The nitride semiconductor device of claim 2, wherein a thickness of the anode layer is less than a thickness of the gate layer.

13. The nitride semiconductor device of claim 2, wherein
the anode layer includes a first side surface and a second side surface facing opposite to each other along the first direction, and
the first side surface is covered with the passivation layer, and the second side surface is exposed through the second opening.

14. The nitride semiconductor device of claim 3, wherein
the anode layer includes a first side surface and a second side surface facing opposite to each other along the first direction, and
the first side surface is covered with the passivation layer, and the second side surface is exposed through the third opening.

15. The nitride semiconductor device of claim 2, wherein the anode layer includes a portion having a thickness less than a thickness of the gate layer.

16. The nitride semiconductor device of claim 2, wherein the anode layer includes a first portion having a thickness equal to a thickness of the gate layer, and a second portion having a thickness less than the thickness of the gate layer.

17. The nitride semiconductor device of claim 16, wherein
the first portion is covered by the passivation layer, and
the second portion is exposed through the second opening.

18. The nitride semiconductor device of claim 2, wherein the diode region is smaller than the transistor region.

19. The nitride semiconductor device of claim 2, wherein a distance between the second opening and the third opening is less than a distance between the first opening and the second opening.

20. The nitride semiconductor device of claim 2, wherein
the gate layer is formed in an annular shape when viewed from a thickness direction of the substrate in the transistor region,
the drain electrode is surrounded by the gate layer when viewed from the thickness direction of the substrate,
the anode layer is disposed apart from the gate layer and formed in an annular shape when viewed from the thickness direction of the substrate in the diode region,
the cathode electrode is surrounded by the anode layer when viewed from the thickness direction of the substrate.
